(19) United States
(12) Patent Application Publication
(10) Pub. No.: US 2024/0274050 A1
(43) Pub. Date: Aug. 15, 2024

(54) SCAN CIRCUIT, DISPLAY APPARATUS, METHOD OF DRIVING SCAN CIRCUIT

(71) Applicants: Chengdu BOE Optoelectronics Technology Co., Ltd., Chengdu, Sichuan (CN); BOE Technology Group Co., Ltd., Beijing (CN)

(72) Inventors: Song Liu, Beijing (CN); Lu Bai, Beijing (CN); Yang Zhou, Beijing (CN); Xin Zhang, Beijing (CN); Junxiu Dai, Beijing (CN); Liheng Wei, Beijing (CN); Tianci Chen, Beijing (CN); Jiaxing Chen, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 17/907,499

(22) PCT Filed: Dec. 29, 2021
(86) PCT No.: PCT/CN2021/142424

§ 371 Date: Sep. 27, 2022

(51) Int. Cl. G09G 3/20

(52) U.S. Cl. CPC G09G 3/20; G09G 2300/0426; G09G 2310/08

(57) ABSTRACT

A scan circuit is provided. The scan circuit includes a plurality of stages. A respective stage of the scan circuit includes a first scan unit and a second scan unit configured to provide control signals to different rows of subpixels. Output from the first scan unit is input to the second scan unit through one of M rows of subpixels. M is an integer ≥2.

### TECHNICAL FIELD

The present invention relates to display technology, more particularly, to a scan circuit, a display apparatus, and method of driving a scan circuit.

### BACKGROUND

Image display apparatuses include a driver for controlling image display in each of a plurality of pixels. The driver is a transistor-based circuit including a gate driving circuit and a data driving circuit. The gate driving circuit is formed by cascading multiple units of shift register units. Each shift register unit outputs a gate driving signal to one of a plurality of gate lines. The gate driving signals from the gate driving circuit scan through gate lines row by row, controlling each row of transistors to be in on/off states. The gate drive circuit can be integrated into a gate-on-array (GOA) circuit, which can be formed directly in the array substrate of the display panel.

### SUMMARY

In one aspect, the present disclosure provides a scan circuit, comprising a plurality of stages, wherein a respective stage of the scan circuit comprises a first scan unit and a second scan unit configured to provide control signals to different rows of subpixels, output from the first scan unit being input to the second scan unit through at least one of M rows of subpixels, M being an integer ≥2.

Optionally, the first scan unit and the second scan unit are configured to provide control signals to the M rows of subpixels in a display panel, the first scan unit and the second scan unit being on two opposite sides of the M rows of subpixels, respectively.

Optionally, a length of each of the first scan unit and the second scan unit along a column direction spans over the M rows of subpixels.

Optionally, a ratio of a total number of scan units of the scan circuit to a total number of rows of subpixels is (2/M), wherein M≥4.

Optionally, M=4.

Optionally, an n-th stage of the scan circuit comprises a first n-th stage scan unit and a second n-th stage scan unit, n is an integer >1; wherein the first n-th stage scan unit is configured to receive an output signal from a (n−1)-th stage of the scan circuit as an input signal; an output signal from the first n-th stage scan unit is provided to m1 number of rows of the M rows of subpixels as control signals therein, and subsequently input to the second n-th stage scan unit as an input signal thereof, m1 is an integer <M; and an output signal from the second n-th stage scan unit is provided to m2 number of rows of the M rows of subpixels as control signals therein, and subsequently input to a (n+1)th-stage of the scan circuit as an input signal thereof, m2 is an integer <M, (m1+m2)=M.

Optionally, the n-th stage of the scan circuit further comprises m1 number of output branch lines, a respective one of which configured to transmit the output signal from the first n-th stage scan unit to a respective one of the m1 number of rows of the M rows of subpixels, and m2 number of output branch lines, a respective one of which configured to transmit the output signal from the second n-th stage scan unit to a respective one of the m2 number of rows of the M rows of subpixels.

Optionally, all of the m1 number of output branch lines are electrically connected to second electrodes of a ninth transistor and a tenth transistor of the first n-th stage scan unit, and electrically connected to an input signal line of the second n-th stage scan unit; and all of the m2 number of output branch lines are electrically connected to second electrodes of a ninth transistor and a tenth transistor of the second n-th stage scan unit, and electrically connected to an input signal line of the (n+1)-stage of the scan circuit.

Optionally, the n-th stage of the scan circuit further comprises 2M number of gate scanning signal generating units and 2M number of reset control signal generating units; wherein a respective row of the M rows of subpixels is connected to two gate scanning signal generating units of the 2M number of gate scanning signal generating units on two opposite sides, respectively, and is connected to two reset control signal generating units of the 2M number of reset control signal generating units on two opposite sides, respectively; wherein the first n-th stage scan unit is configured to output light emitting control signals to the m1 number of rows of the M rows of subpixels; the second n-th stage scan unit is configured to output light emitting control signals to the m2 number of rows of the M rows of subpixels; the 2M number of gate scanning signal generating units are configured to output gate scanning signals to the M rows of subpixels; and the 2M number of reset control signal generating units are configured to output reset control signals to the M rows of subpixels.

Optionally, the scan circuit further comprises a first voltage supply line and a second voltage supply line; wherein transistors of a respective scan unit of the first and second scan units are arranged in a region between the first voltage supply line and the second voltage supply line.

Optionally, the respective scan unit comprises a ninth transistor and a tenth transistor, second electrodes of which are connected to an output signal line configured to output control signals from the respective scan unit to rows of subpixels; wherein the ninth transistor and the tenth transistor are in a first region, transistors other than the ninth transistor and the tenth transistor are in a second region, the first region and the second region are sequentially arranged along extension directions of the first voltage supply line and the second voltage supply line.

Optionally, the respective scan unit further comprises a second capacitor and a third capacitor in a third region, the first region, the third region, and the second region are sequentially arranged along the extension directions of the first voltage supply line and the second voltage supply line, the first region, the third region, and the second region being non-overlapping.

Optionally, the scan circuit further comprises a first signal line layer; wherein the first signal line layer comprises a first voltage supply line, a second voltage supply line, a first connecting line, a second connecting line, a third connecting line, a fourth connecting line, and a fifth connecting line; wherein at least portions of the first connecting line, the second connecting line, the third connecting line, the fourth connecting line, and the fifth connecting line are substantially parallel to extension directions of the first voltage supply line and the second voltage supply line.

Optionally, the first connecting line electrically connects gate electrodes of a second transistor and an eighth transistor; the second connecting line electrically connects a second electrode of a sixth transistor with a first electrode of a seventh transistor, and is connected to a second capacitor electrode of a first capacitor through one or more vias extending through an inter-layer dielectric layer; the third connecting line electrically connects a first electrode of the sixth transistor with a gate electrode of the seventh transistor; the fourth connecting line electrically connects a gate electrode of a fifth transistor, a second electrode of a second transistor, a first electrode of an eleventh transistor, and a second electrode of a third transistor together; and the fifth connecting line electrically connects a gate electrode of a fourth transistor with a second electrode of a twelfth transistor.

Optionally, the scan circuit further comprises a first conductive layer; wherein the first conductive layer comprises a sixth connecting line electrically connecting a second clock signal line with gate electrodes of a fourth transistor, a fifth transistor, and a seventh transistor; and the sixth connecting line crosses over the fourth connecting line and the fifth connecting line, and is connected to the third connecting line through one or more vias extending through an insulating layer and an inter-layer dielectric layer.

Optionally, the first conductive layer further comprises a seventh connecting line electrically connecting a second voltage supply line with gate electrodes of an eleventh transistor and a twelfth transistor; and the seventh connecting line crosses over the fourth connecting line.

Optionally, the first conductive layer further comprises an eighth connecting line electrically connecting a gate electrode of a second transistor with the first connecting line, a second electrode of a first transistor, and a first electrode of a twelfth transistor; the eighth connecting line crosses over the fourth connecting line.

Optionally, the first conductive layer further comprises a ninth connecting line electrically connecting a first clock signal line with gate electrodes of a first transistor and a third transistor.

Optionally, the scan circuit comprises a first gate layer, a second gate layer, a first conductive layer, a second conductive layer, and a first signal line layer; wherein the first gate layer, the second gate layer, the first conductive layer, and the first signal line layer in the first scan unit and in the second scan unit have a mirror symmetry; and the second conductive layer in the first scan unit and in the second scan unit have a mirror symmetry except for output signal lines therein.

In another aspect, the present disclosure provides a display apparatus, comprising the scan circuit described herein, and a display panel comprising a plurality of light emitting elements.

In another aspect, the present disclosure provides a method of driving the scan circuit described herein, comprising inputting an output signal from the (n−1)-th stage of the scan circuit into the first n-th stage scan unit as an input signal thereof; outputting a first control signal from the first n-th stage scan unit to the m1 number of rows of the M rows of subpixels; subsequent to outputting the first control signal through subpixels in the m1 number of rows of the M rows of subpixels, inputting the first control signal to the second n-th stage scan unit as an input signal thereof; and outputting a second control signal from the second n-th stage scan unit to the m2 number of rows of the M rows of subpixels.

### BRIEF DESCRIPTION OF THE FIGURES

The following drawings are merely examples for illustrative purposes according to various disclosed embodiments and are not intended to limit the scope of the present invention.

FIG. 1A is a schematic diagram illustrating the structure of a scan circuit in some embodiments according to the present disclosure.

FIG. 1B is a schematic diagram illustrating the structure of a scan circuit in some embodiments according to the present disclosure.

FIG. 2 is a circuit diagram of a respective scan unit in some embodiments according to the present disclosure.

FIG. 3 is a timing diagram illustrating an operation of the stage of a scan unit illustrated in FIG. 2.

FIG. 4 is a circuit diagram of a respective scan unit in some embodiments according to the present disclosure.

FIG. 5 is a schematic diagram illustrating a display region and a peripheral area in a display panel in some embodiments according to the present disclosure.

FIG. 6A illustrates a detailed structure in a display region in a display panel in some embodiments according to the present disclosure.

FIG. 6B illustrates a detailed structure in a display region in a display panel in some embodiments according to the present disclosure.

FIG. 7A illustrates the structure of a first n-th stage scan unit in some embodiments according to the present disclosure.

FIG. 7B illustrates the structure of a semiconductor material layer in the first n-th stage scan unit depicted in FIG. 7A.

FIG. 7C illustrates the structure of a first conductive layer in the first n-th stage scan unit depicted in FIG. 7A.

FIG. 7D illustrates the structure of a second conductive layer in the first n-th stage scan unit depicted in FIG. 7A.

FIG. 7E illustrates the structure of an inter-layer dielectric layer in the first n-th stage scan unit depicted in FIG. 7A.

FIG. 7F illustrates the structure of a first signal line layer in the first n-th stage scan unit depicted in FIG. 7A.

FIG. 8A illustrates the structure of a second n-th stage scan unit in some embodiments according to the present disclosure.

FIG. 8B illustrates the structure of a semiconductor material layer in the second n-th stage scan unit depicted in FIG. 8A.

FIG. 8C illustrates the structure of a first conductive layer in the second n-th stage scan unit depicted in FIG. 8A.

FIG. 8D illustrates the structure of a second conductive layer in the second n-th stage scan unit depicted in FIG. 8A.

FIG. 8E illustrates the structure of an inter-layer dielectric layer in the second n-th stage scan unit depicted in FIG. 8A.

FIG. 8F illustrates the structure of a first signal line layer in the second n-th stage scan unit depicted in FIG. 8A.

FIG. 9 is a schematic diagram illustrating the structure of a peripheral area of a display apparatus in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a scan circuit, a display apparatus, and a method of driving a scan circuit that substantially obviate one or more of the problems due to limitations and disadvantages of the related art. In one aspect, the present disclosure provides a scan circuit having a plurality of stages. In some embodiments, a respective stage of the scan circuit includes a first scan unit and a second scan unit configured to provide control signals to different rows of subpixels. Optionally, output from the first scan unit is input to the second scan unit through at least one of M rows of subpixels, M being an integer ≥2. Optionally, the first scan unit and the second scan unit are configured to provide control signals to M rows of subpixels in a display panel, the first scan unit and the second scan unit being on two opposite sides of the M rows of subpixels.

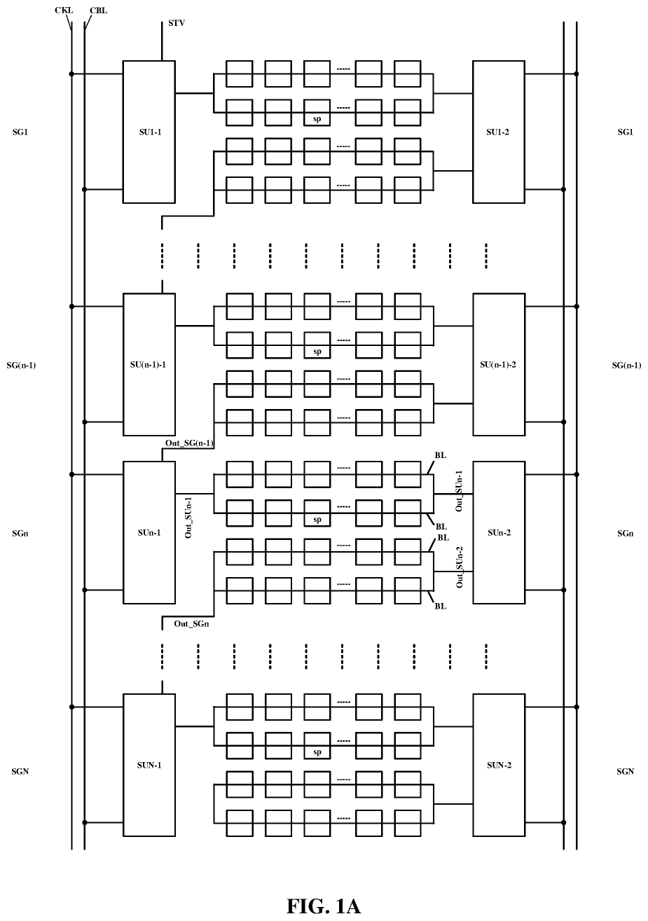

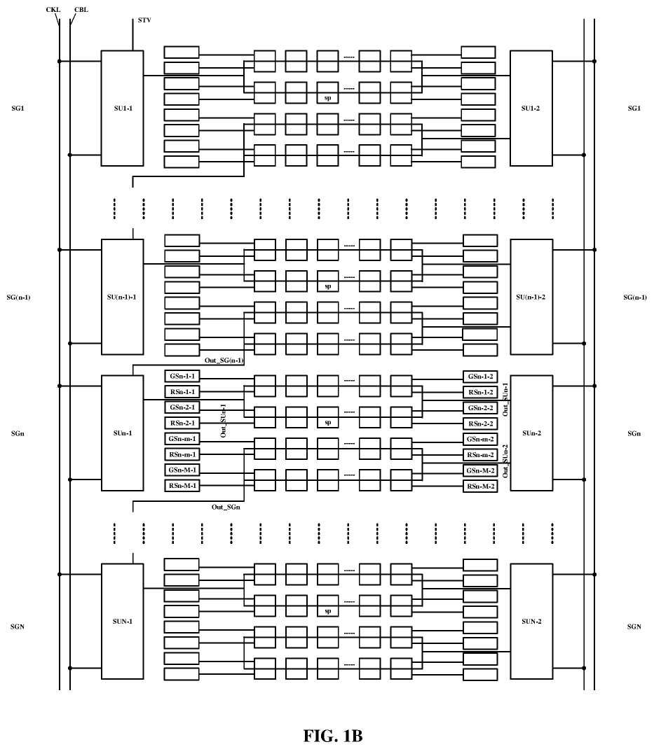

FIG. 1A is a schematic diagram illustrating the structure of a scan circuit in some embodiments according to the present disclosure. Referring to FIG. 1A, the scan circuit includes N stages, e.g., a first stage SG1, . . . , a (n−1)-th stage SG(n-1), an n-th stage SGn, . . . , and an N-th stage SGN, N is an integer ≥2. A respective stage of the scan circuit includes two scan units, for example, the first stage SG1 includes a first first stage scan unit SU1-1 and a second first stage scan unit SU1-2, the (n−1)-th stage SG(n-1) includes a first (n−1)-th stage scan unit SU(n-1)-1 and a second (n−1)-th stage scan unit SU(n-1)-2, the n-th stage SGn includes a first n-th stage scan unit SUn-1 and a second n-th stage scan unit SUn-2, and the N-th stage SGn includes a first N-th stage scan unit SUN-1 and a second N-th stage scan unit SUN-2. The two scan units in the respective stage of the scan circuit are configured to provide control signals to M rows of subpixels sp in a display panel, M>4, the two scan units being on two opposite sides of the M rows of subpixels. FIG. 1A shows an example in which M=4. For example, the first n-th stage scan unit SUn-1 and the second n-th stage scan unit SUn-2 are configured to provide control signals to four rows of subpixels sp, wherein the first n-th stage scan unit SUn-1 is configured to provide control signals to the first two rows of subpixel sp, and the second n-th stage scan unit SUn-2 is configured to provide control signals to the last two rows of subpixel sp.

Referring to FIG. 1A, the first stage SG1 (more specifically, the first first stage scan unit SU1-1) is configured to receive a start signal STV as its input. The other stages are configured to receive an output signal from a previous stage as its input. For example, the n-th stage SGn (more specifically, the first n-th stage scan unit SUn-1) is configured to receive an output signal Out_SG(n-1) from the (n−1)-th stage SG(n-1) as its input.

Referring to FIG. 1A, the first scan unit and the second scan unit in a same stage are configured to provide control signals to different rows of subpixels, for example, the first scan unit is configured to provide control signals to the first row and the second row of subpixels of the M rows of subpixels sp, and the second scan unit is configured to provide control signals to the third row and the fourth row of subpixels of the M rows of subpixels sp. Optionally, M is an integer ≥4, e.g., 4, 5, 6, 7, 8, 9, 10.

In some embodiments, output from the first scan unit is input to the second scan unit. For example, output Out_SUn-1 from the first n-th stage scan unit SUn-1 is used as input to the second n-th stage scan unit SUn-2.

As shown in FIG. 1A, a length of the first scan unit along a column direction spans over the M rows of subpixels; and a length of the second scan unit along the column direction spans over the same M rows of subpixels. In some embodiments, a ratio of a total number of scan units of the scan circuit to a total number of rows of subpixels is (2/M), wherein M≥4.

In some embodiments, an n-th stage of the scan circuit comprises a first n-th stage scan unit and a second n-th stage scan unit, n is an integer >1. The first n-th stage scan unit is configured to receive an output signal Out_SG(n-1) from a (n−1)-th stage of the scan circuit as an input signal. An output signal Out_SUn-1 from the first n-th stage scan unit SUn-1 is provided to m1 number of rows of the M rows of subpixels (in FIG. 1A, first two rows) as control signals therein, and subsequently input to the second n-th stage scan unit SUn-2 as an input signal thereof, m1 is an integer and m1<M. An output signal Out_SUn-2 from the second n-th stage scan unit SUn-2 is provided to m2 number of rows of the M rows of subpixels (In FIG. 1A, last two rows) as control signals therein, and subsequently input to a (n+1)-th stage of the scan circuit as an input signal thereof, m2 is an integer <M, (m1+m2)=M. In one example, m1=m2=2. Optionally, m1=m2=M/2.

In some embodiments, the n-th stage SGn of the scan circuit further includes M number of branch lines BL. The M number of branch lines BL (in FIG. 1A, four branch lines) includes m1 number of output branch lines (in FIG. 1A, the first two branch lines) and m2 number of output branch lines (in FIG. 1A, the last two branch lines). A respective one of the m1 number of output branch lines is configured to transmit the output signal from the first n-th stage scan unit SUn-1 to a respective one of the m1 number of rows of the M rows of subpixels. A respective one of the m2 number of output branch lines is configured to transmit the output signal from the second n-th stage scan unit SUn-2 to a respective one of the m2 number of rows of the M rows of subpixels.

In some embodiments, each branch line crosses over a respective row of subpixel. A total number of branch lines equals to a total number of rows of subpixels.

In some embodiments, the n-th stage SGn of the scan circuit further includes an output signal line configured to transmit the output signal Out_SUn-2 from the second n-th stage scan unit SUn-2 to a (n+1)-th stage of the scan circuit, subsequent to that the output signal Out_SUn-2 being provided to the m2 number of rows of the M rows of subpixels. The output signal from the n-th stage SGn of the scan circuit is denoted by an output signal Out_SGn, which is used as an input signal in the (n+1)-th stage of the scan circuit.

FIG. 1B is a schematic diagram illustrating the structure of a scan circuit in some embodiments according to the present disclosure. Referring to FIG. 1B, the scan circuit in some embodiments further includes N*2M number of gate scanning signal generating units and N*2M number of reset control signal generating units. In some embodiments, the n-th stage SGn of the scan circuit includes 2M number of gate scanning signal generating units and 2M number of reset control signal generating units. Optionally, the first n-th stage scan unit is configured to output light emitting control signals to the m1 number of rows of the M rows of subpixels; the second n-th stage scan unit is configured to output light emitting control signals to the m2 number of rows of the M rows of subpixels; the 2M number of gate scanning signal generating units are configured to output gate scanning signals to the M rows of subpixels; and the 2M number of reset control signal generating units are configured to output reset control signals to the M rows of subpixels. Optionally, a respective row of the M rows of subpixels is connected to two gate scanning signal generating units of the 2M number of gate scanning signal generating units on two opposite sides, respectively, and is connected to two reset control signal generating units of the 2M number of reset control signal generating units on two opposite sides, respectively.

As shown in FIG. 1B, in the n-th stage of the scan circuit, M number of gate scanning signal first generating units, GSn-1-1, GSn-2-1, . . . , GSn-m-1, . . . , GSn-M-1, are arranged on the left side of the M rows of subpixels. A m-th gate scanning signal first generating unit, GSn-m-1, is configured to provide a m-th gate scanning signal to a m-th row of the M rows of subpixels from the left side. In the n-th stage of the scan circuit, M number of gate scanning signal second generating units, GSn-1-2, GSn-2-2, . . . , GSn-m-2, . . . , GSn-M-2, are arranged on the right side of the M rows of subpixels. A m-th gate scanning signal second generating unit, GSn-m-2, is configured to provide a m-th gate scanning signal to a m-th row of the M rows of subpixels from the right side.

As shown in FIG. 1B, in the n-th stage of the scan circuit, M number of reset control signal first generating units, RSn-1-1, RSn-2-1, . . . , RSn-m-1, . . . , RSn-M-1, are arranged on the left side of the M rows of subpixels. A m-th reset control signal first generating unit, RSn-m-1, is configured to provide a m-th reset control signal to a m-th row of the M rows of subpixels from the left side. In the n-th stage of the scan circuit, M number of reset control signal second generating units, RSn-1-2, RSn-2-2, . . . , RSn-m-2, . . . , RSn-M-2, are arranged on the right side of the M rows of subpixels. A m-th reset control signal second generating unit, RSn-m-2, is configured to provide a m-th reset control signal to a m-th row of the M rows of subpixels from the right side.

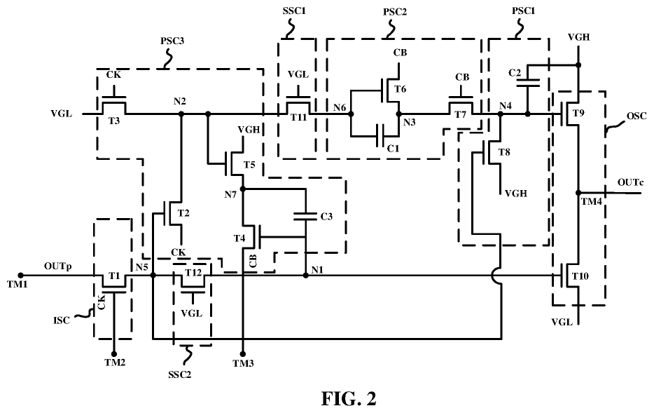

Various appropriate scan units may be used in the present scan circuit. FIG. 2 is a circuit diagram of a respective scan unit in some embodiments according to the present disclosure. Referring to FIG. 2, the respective scan unit in some embodiments includes an input subcircuit ISC, an output subcircuit OSC, a first processing subcircuit PSC1, a second processing subcircuit PSC2, a third processing subcircuit PSC3, a first stabilizing subcircuit SSC1, and a second stabilizing subcircuit SSC2. The respective scan unit illustrated in FIG. 2 may be a first scan unit or a second scan unit.

In some embodiments, the output subcircuit OSC is configured to supply the voltage of a first power supply VGH or a second power supply VGL to an output terminal TM4 in response to voltages of a fourth node N4 and a first node N1. Optionally, the output subcircuit OSC includes a ninth transistor T9 and a tenth transistor T10.

The ninth transistor T9 is coupled between a first power supply VGH and the output terminal TM4. A gate electrode of the ninth transistor T9 is coupled to the fourth node N4. The ninth transistor T9 may be turned on or off depending on the voltage of the fourth node N4. Optionally, when the ninth transistor T9 is turned on, the voltage of the first power supply VGH is provided to the output terminal TM4, which (annotated as Outc in FIG. 2) may be transmitted to a n-th gate line and used as a gate driving signal having a gate-on level.

The tenth transistor T10 is coupled between the output terminal TM4 and a second power supply VGL. A gate electrode of the tenth transistor T10 is coupled to the first node N1. The tenth transistor T10 may be turned on or off depending on the voltage of the first node N1. Optionally, when the tenth transistor T10 is turned on, the voltage of the second power supply VGL is provided to the output terminal TM4, which (annotated as Outc in FIG. 2) may be provided to a n-th gate line and used as a gate driving signal having a gate-off level. In one example, when the gate driving signal has a gate-off level, it may be understood that the gate driving signal is not provided.

In some embodiments, the input subcircuit ISC is configured to control the voltages of the first node N1 and a fifth node N5 in response to signals provided to the first input terminal TM1 and the second input terminal TM2, respectively. Optionally, the input subcircuit ISC includes a first transistor T1.

The first transistor T1 is coupled between the first input terminal TM1 and the fifth node N5. A gate electrode of the first transistor T1 is coupled to the second input terminal TM2. When the first clock signal CK is provided to the second input terminal TM2, the first transistor T1 is turned on to electrically couple the first input terminal TM1 with the fifth node N5.

In some embodiments, the first processing subcircuit PSC1 is configured to control the voltage of the fourth node N4 in response to the voltages of the first node N1 and the fifth node N5. Optionally, the first processing subcircuit PSC1 includes an eighth transistor T8 and a second capacitor C2.

The eighth transistor T8 is coupled between the first power supply VGH and the fourth node N4. A gate electrode of the eighth transistor T8 is coupled to the fifth node N5. The eighth transistor T8 may be turned on or off depending on the voltage of the fifth node N5. Optionally, when the eighth transistor T8 is turned on, the voltage of the first power supply VGH may be provided to the fourth node N4.

The second capacitor C2 is coupled between the first power supply VGH and the fourth node N4. Optionally, the second capacitor C2 is configured to charge a voltage to be applied to the fourth node N4. Optionally, the second capacitor C2 is configured to stably maintain the voltage of the fourth node N4.

In some embodiments, the second processing subcircuit PSC2 is coupled to a sixth node N6, and is configured to control the voltage of the fourth node N4 in response to a signal input to the third input terminal TM3. Optionally, the second processing subcircuit PSC2 includes a sixth transistor T6, a seventh transistor T7, and a first capacitor C1.

A first terminal of the first capacitor C1 is coupled to the sixth node N6, and a second terminal of the first capacitor C1 is coupled to a third node N3 that is a common node between the sixth transistor T6 and the seventh transistor T7.

The sixth transistor T6 is coupled between the third node N3 and the sixth node N6. A gate electrode of the sixth transistor T6 is coupled to the sixth node N6. The sixth transistor T6 may be turned on depending on the voltage of the sixth node N6 so that a voltage corresponding to the second clock signal CB provided to the third input terminal TM3 may be applied to the third node N3.

The seventh transistor T7 is coupled between the fourth node N4 and the third node N3. A gate electrode of the seventh transistor T7 is coupled to the third input terminal TM3. The seventh transistor T7 may be turned on in response to the second clock signal CB provided to the third input terminal TM3, and thus, applies the voltage of the first power supply VGH to the third node N3.

In some embodiments, the third processing subcircuit PSC3 is configured to control the voltage of the second node N2. Optionally, the third processing subcircuit PSC3 includes a second transistor T2, a third transistor T3, a fourth transistor T4, a fifth transistor T5, and a third capacitor C3.

A first electrode of the third capacitor C3 is coupled to the first node N1, and a second electrode of the third capacitor C3 is coupled to a seventh node N7 that is a common node between the fourth transistor T4 and the fifth transistor T5.

The fifth transistor T5 is coupled between the first power supply VGH and the seventh node N7. A gate electrode of the fifth transistor T5 is coupled to the second node N2. The fifth transistor T5 may be turned on or off depending on the voltage of the second node N2.

The fourth transistor T4 is coupled between the seventh node N7 and the third input terminal TM3. A gate electrode of the fourth transistor T4 is coupled to the first node N1. The fourth transistor T4 may be turned on or off depending on the voltage of the first node N1.

The second transistor T2 is coupled between the second node N2 and the second input terminal TM2. A gate electrode of the second transistor T2 is coupled to the fifth node N5.

The third transistor T3 is coupled between the second node N2 and the second power supply VGL. A gate electrode of the third transistor T3 is coupled to the second input terminal TM2. When the first clock signal CK is provided to the second input terminal TM2, the third transistor T3 may be turned on so that the voltage of the second power supply VGL may be provided to the second node N2.

In some embodiments, the first stabilizing subcircuit SSC1 is coupled between the second processing subcircuit PSC2 and the third processing subcircuit PSC3. Optionally, the first stabilizing subcircuit SSC1 is configured to limit a voltage drop width of the second node N2. Optionally, the first stabilizing subcircuit SSC1 includes an eleventh transistor T11.

The eleventh transistor T11 is coupled between the second node N2 and the sixth node N6. A gate electrode of the eleventh transistor T11 is coupled to the second power supply VGL. Since the second power supply VGL has a gate-on level voltage, the eleventh transistor T11 may always remain turned on. Therefore, the second node N2 and the sixth node N6 may be maintained at the same voltage, and operated as substantially the same node.

In some embodiments, the second stabilizing subcircuit SSC2 is coupled between the first node N1 and the fifth node N5. Optionally, the second stabilizing subcircuit SSC2 is configured to limit a voltage drop width of the first node N1. Optionally, the second stabilizing subcircuit SSC2 includes a twelfth transistor T12.

The twelfth transistor T12 is coupled between the first node N1 and the fifth node N5. A gate electrode of the twelfth transistor T12 is coupled to the second power supply VGL. Since the second power supply VGL has a gate-on level voltage, the twelfth transistor T12 may always remain turned on. Therefore, the first node N1 and the fifth node N5 may be maintained at the same voltage, and operated as substantially the same node.

In some embodiments, each of the first to twelfth transistors T1 to T12 may be formed of a p-type transistor. In some embodiments, the gate-on voltage of the first to twelfth transistors T1 to T12 may be set to a low level, and the gate-off voltage thereof may be set to a high level.

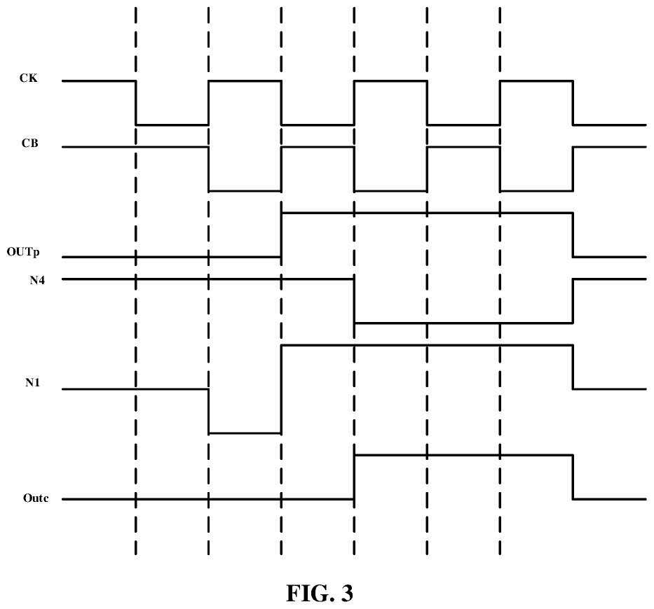

FIG. 3 is a timing diagram illustrating an operation of the scan unit of the stage illustrated in FIG. 2. Referring to FIG. 3, the first clock signal CK and the second clock signal CB each may have a cycle of two horizontal periods (2H), and have a gate-on level during different horizontal periods. Optionally, the second clock signal CB may be set to a signal shifted by a half cycle (i.e., one horizontal period (1H)) from the first clock signal CK.

In some embodiments, when the clock signals CK and CB are provided, the second input terminal TM2 and the third input terminal TM3 may be set to the low level, i.e., the voltage of the second power supply VGL. When the clock signals CK and CB are not provided, the second input terminal TM2 and the third input terminal TM3 may be set to the high level, i.e., the voltage of the first power supply VGH.

In some embodiments, when a start signal STV or an output signal Outp from an output terminal of a previous scan unit (e.g., a previous scan unit of a same stage or a previous scan unit of a previous stage) is provided, the first input terminal TM1 may be set to the high level, i.e., the voltage of the first power supply VGH. When the start signal STV or the output signal Outp from the output terminal of the previous scan unit is not provided, the first input terminal TM1 may be set to the low level, i.e., the voltage of the second power supply VGL.

In some embodiments, the start signal STV or the output signal Outp from the output terminal of the previous scan unit to be provided to the first input terminal TM1 may be set to overlap at least once with the first clock signal CK to be provided to the second input terminal TM2. Optionally, the start signal STV or the output signal Outp from the output terminal of the previous scan unit may have a width greater than that of the first clock signal CK and, for example, be provided during four horizontal periods (4H). In this case, an output signal to be provided to the first input terminal TM1 of the next stage may also overlap at least once with the second clock signal CB to be provided to the second input terminal TM2 of the next stage.

In some embodiments, during a first period t1, the first clock signal CK is provided to the second input terminal TM2. The first transistor T1 and the fifth transistor T5 are turned on. Furthermore, during the first period t1, the second clock signal CB is not provided to the third input terminal TM3, the seventh transistor T7 is turned off.

In some embodiments, when the first transistor T1 is turned on, the first input terminal TM1 and the fifth node N5 are electrically coupled to each other. The twelfth transistor T12 remains turned on, the first input terminal TM1 is electrically coupled with the first node N1 via the fifth node N5.

In some embodiments, during the first period t1, the start signal STV or the output signal Outp from the output terminal of the previous scan unit to be provided to the first input terminal TM1 has the low level, a low voltage (e.g., the voltage of the second power supply VGL) may be applied to the fifth node N5 and the first node N1. When the fifth node N5 and the first node N1 are set to the low voltage, the third transistor T3, the fourth transistor T4, the eighth transistor T8, and the tenth transistor T10 are turned on.

In some embodiments, when the fourth transistor T4 is turned on, the third input terminal TM3 and the seventh node N7 are electrically coupled to each other. The second clock signal CB is not provided to the third input terminal TM3 during the first period t1, a high voltage may be provided to the seventh node N7. The third capacitor C3 is configured to charge a voltage corresponding to the turned-on state of the fourth transistor T4.

In some embodiments, when the fourth transistor T4 is turned on, the fifth transistor T5 is connected in the form of a diode between the second node N2 and the first power supply VGH. When the fifth transistor T5 is turned on during the first period t1, the voltage of the first power supply VGH is not transmitted to the second node N2, and the voltage of the second node N2 is maintained at the voltage of the preceding state, e.g., the high voltage. The eleventh transistor T11 remains turned on, the high voltage of the second node N2 is applied to the sixth node N6, and the sixth node N6 is set to the high voltage. The second transistor T2 and the sixth transistor T6 are turned off.

In some embodiments, when the eighth transistor T8 is turned on, the voltage of the first power supply VGH is provided to the fourth node N4. The ninth transistor T9 is turned off.

In some embodiments, when the tenth transistor T10 is turned on, the voltage of the second power supply VGL is provided to the output terminal TM4. During the first period t1, the gate driving signal are not provided to the n-th stage gate line.

In some embodiments, during a second period t2, the supply of the first clock signal CK to the second input terminal TM2 is interrupted. The first transistor T1 and the fifth transistor T5 are turned off. The fourth node N4 and the first node N1 maintain the voltages of the preceding period by the second capacitor C2 and the third capacitor C3. Since the fourth node N4 remains in the high voltage state, the ninth transistor T9 remains turned off. Since the first node N1 remains in the low voltage state, the second transistor T2, the fourth transistor T4, the eighth transistor T8, and the tenth transistor T10 remain turned on.

In some embodiments, during the second period t2, the second clock signal CB is provided to the third input terminal TM3. The seventh transistor T7 is turned on by the second clock signal CB provided to the third input terminal TM3. When the seventh transistor T7 is turned on, the fourth node N4 and the third node N3 are electrically coupled to each other. The third node N3 is set to the high voltage.

In some embodiments, during the second period t2, the second clock signal CB is provided to the seventh node N7 via the fourth transistor T4 that is turned on. A low voltage is provided to the seventh node N7. The voltage of the first node N1 is maintained at a voltage (a 2-step low voltage) less than the voltage of the second power supply VGL by coupling of the third capacitor C3.

In some embodiments, during a third period t3, the supply of the second clock signal CB to the third input terminal TM3 is interrupted. When the supply of the second clock signal CB is interrupted, the seventh transistor T7 is turned off.

In some embodiments, during the third period t3, the start signal STV or the output signal Outp from the output terminal of the previous scan unit is provided to the first input terminal TM1, and the first clock signal CK is provided to the second input terminal TM2. When the first clock signal CK is provided to the second input terminal TM2, the first transistor T1 and the fifth transistor T5 are turned on.

In some embodiments, when the first transistor T1 is turned on, the first input terminal TM1 and the fifth node N5 are electrically coupled to each other. The twelfth transistor T12 remains turned on, the first input terminal TM1 is electrically coupled with the first node N1 via the fifth node N5. The fifth node N5 and the first node N1 are set to the high voltage by the start signal STV or the output signal Outp from the output terminal of the previous scan unit that is provided to the first input terminal TM1. When the fifth node N5 and the first node N1 are set to the high voltage, the second transistor T2, the fourth transistor T4, the eighth transistor T8, and the tenth transistor T10 are turned off.

In some embodiments, when the fifth transistor T5 is turned on, the low voltage of the second power supply VGL is applied to the second node N2 so that the second node N2 and the sixth node N6 are set to the low voltage. The second transistor T2 and the sixth transistor T6 may be turned on.

In some embodiments, when the fifth transistor T5 is turned on, the voltage of the first power supply VGH is applied to the seventh node N7. The seventh node N7 is maintained at the high voltage. Since the fourth transistor T4 remains turned off, the voltage of the second clock signal CB to be applied to the third input terminal TM3 is not transmitted to the seventh node N7. Since both the seventh node N7 and the first node N1 that are the opposite ends of the third capacitor C3 are maintained at the high voltage, the third capacitor C3 is not charged or discharged. A current path is formed from the first power supply VGH to the first node N1 via the fifth transistor T5, and the high voltage of the first power supply VGH is transmitted to the first node N1. The voltage of the first node N1 is stably maintained at the high level.

In some embodiments, when the sixth transistor T6 is turned on, the third input terminal TM3 and the third node N3 are electrically coupled to each other. Since the second clock signal CB is not provided to the third input terminal TM3 during the third period t3, the third node N3 is maintained at the high voltage. Since the seventh transistor T7 remains turned off, the voltage of the third node N3 does not affect the voltage of the fourth node N4. The first capacitor C1 is configured to store a voltage corresponding to the turn-on level of the sixth transistor T6.

In some embodiments, during a fourth period t4, the second clock signal CB may be provided to the third input terminal TM3. When the second clock signal CB is provided to the third input terminal TM3, the seventh transistor T7 is turned on.

In some embodiments, when the seventh transistor T7 is turned on, the fourth node N4 and the third node N3 are electrically coupled to each other. The low voltage of the second clock signal CB that is provided to the third input terminal TM3 via the sixth transistor T6 that remains turned on is provided to the third node N3 and the fourth node N4. When the low voltage is provided to the fourth node N4, the ninth transistor T9 is turned on.

In some embodiments, when the ninth transistor T9 is turned on, the voltage of the first power supply VGH is provided to the output terminal TM4. The voltage of the first power supply VGH that is provided to the output terminal TM4 is provided to the n-th stage gate line as the gate driving signal.

In some embodiments, during a fifth period t5, the supply of the second clock signal CB to the third input terminal TM3 is interrupted. When the supply of the second clock signal CB is interrupted, the seventh transistor T7 is turned off. The fourth node N4 is stably maintained at the high voltage by the second capacitor C2. The ninth transistor T9 remains turned on, and the voltage of the first power supply VGH is provided to the n-th stage gate line as the gate driving signal.

Although the supply of the second clock signal CB is interrupted during the fifth period t5, the fourth transistor T4 remains turned off and, therefore, the voltage of the second clock signal CB is not provided to the seventh node N7 and does not affect the voltage of the first node N1.

As described above, in some embodiments, during the supply of the gate driving signal, the fourth transistor T4 that remains turned off prevents a change in voltage of the second clock signal CB from affecting the first node N1, whereby the first node N1 may be stably maintained at the high voltage. Furthermore, in some embodiments, during the supply of the gate driving signal, the third capacitor C3 is prevented from being charged or discharged. The third capacitor C3 does not perform a charging or discharging operation at any time other than when the voltage of the first node N1 is set to the low level by the coupling of the third capacitor C3. Therefore, in some embodiments, during the supply of the gate driving signal, the third capacitor C3 does not act as a load. Consequently, the power consumption may be reduced, and reliable output of the gate driving signal may be secured.

In FIG. 2 and FIG. 3, the signal output from the output terminal TM4 is denoted by Outc. When the scan unit in FIG. 2 and FIG. 3 is a first scan unit (e.g., a first n-th stage scan unit SUn-1 in FIG. 1A), the output signal is an output Out_SUn-1 as shown in FIG. 1A. When the scan unit in FIG. 2 and FIG. 3 is a second scan unit (e.g., a second n-th stage scan unit SUn-2 in FIG. 1A), the output signal is an output Out_SUn-2.

In FIG. 2 and FIG. 3, the signal received at the first input terminal TM1 is denoted by Outp. When the scan unit in FIG. 2 and FIG. 3 is a first scan unit (e.g., a first n-th stage scan unit SUn-1 in FIG. 1A), the output signal Outp from the output terminal of the previous scan unit is an output signal Out_SG(n-1) from the (n−1)-th stage SG(n-1) as shown in FIG. 1A, and the previous scan unit is a second scan unit in the (n−1)-th stage SG(n-1). When the scan unit in FIG. 2 and FIG. 3 is a second scan unit (e.g., a second n-th stage scan unit SUn-2 in FIG. 1A), the output signal Outp from the output terminal of the previous scan unit is an output signal Out_SUn-1 from the first scan unit (e.g., the first n-th stage scan unit SUn-1 in FIG. 1A) in the same stage, and the previous scan unit is the first scan unit in the same stage.

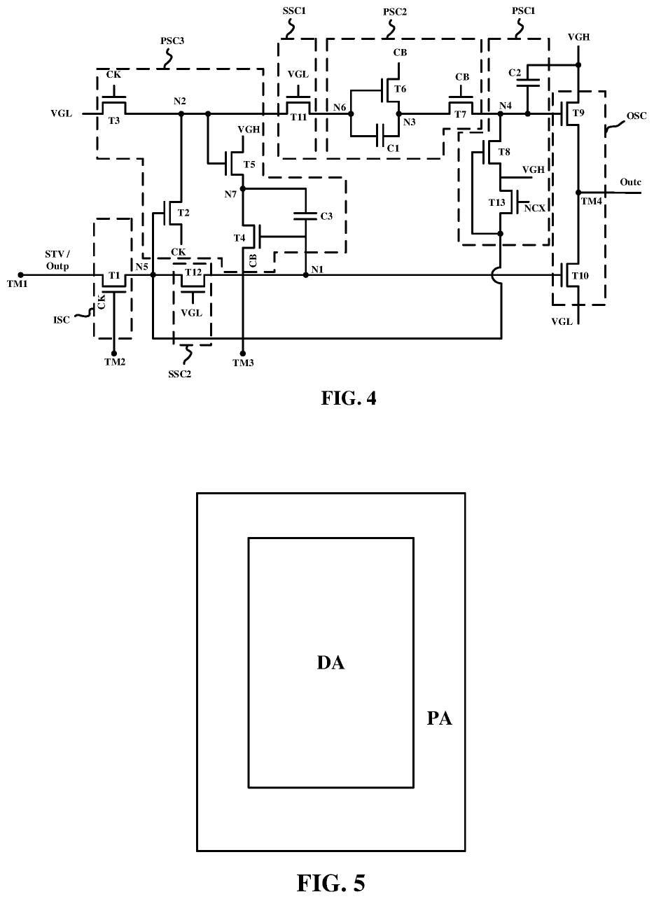

Various appropriate scan units may be used in the present scan circuit. FIG. 4 is a circuit diagram of a respective scan unit in some embodiments according to the present disclosure. The scan unit in FIG. 4 differs from the scan unit in FIG. 3 in that the first processing subcircuit PSC1 further includes a thirteenth transistor T13. The thirteenth transistor T13 is coupled between the first power supply VGH and the fifth node N5. A gate electrode of the thirteenth transistor T13 is coupled to a signal NCX. The thirteenth transistor T13 may be turned on or off depending on the voltage of the signal NCX. Optionally, when the thirteenth transistor T13 is turned on, the voltage of the first power supply VGH may be provided to the fifth node N5.

FIG. 5 is a schematic diagram illustrating a display region and a peripheral area in a display panel in some embodiments according to the present disclosure. Referring to FIG. 5, in some embodiments, the display apparatus includes a display region DA and a peripheral area PA. As used herein, the term “display region” refers to an area of a display panel where image is actually displayed. Optionally, the display region may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels.

The scan circuit in some embodiments is in the peripheral area. As used herein the term “peripheral area” refers to an area of a display panel where various circuits (for example, the scan circuit) and wires are provided to transmit signals to the display panel. To increase the transparency of the display panel, non-transparent or opaque components of the display panel (e.g., battery, printed circuit board, metal frame), can be disposed in the peripheral area rather than in the display regions.

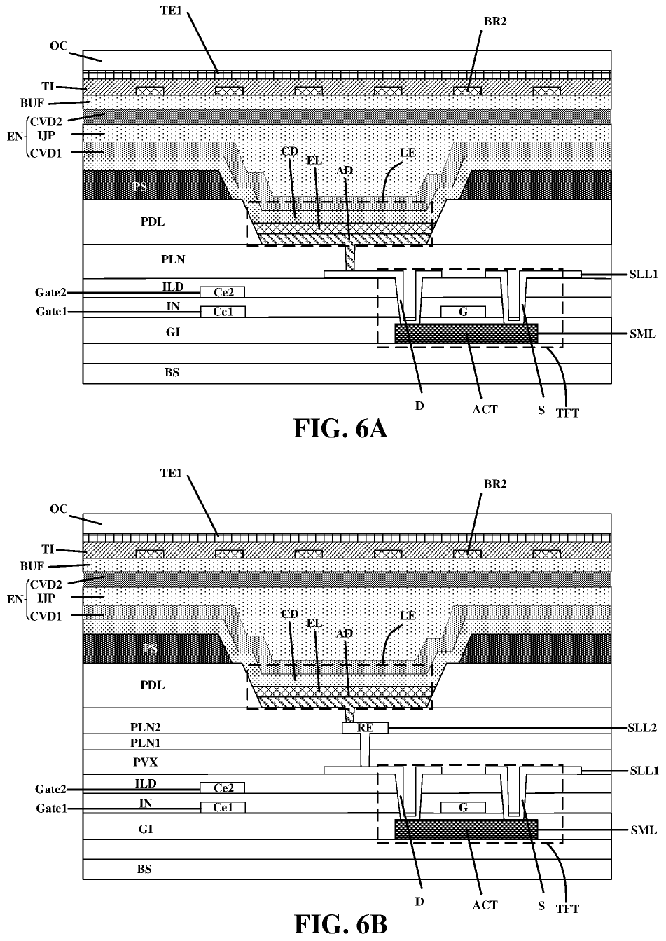

Various implementations of the present display panel may be practiced. FIG. 6A illustrates a detailed structure in a display region in a display panel in some embodiments according to the present disclosure. Referring to FIG. 6A, the display panel in the display region in some embodiments includes a base substrate BS (e.g., a flexible base substrate); an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first conductive layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second conductive layer) on a side of the insulating layer IN away from the gate insulating layer GI; an inter-layer dielectric layer ILD on a side of the second capacitor electrode Ce2 away from the gate insulating layer GI; a first electrode S and a second electrode D (parts of a first SD metal layer) on a side of the inter-layer dielectric layer ILD away from the gate insulating layer GI; a planarization layer PLN on a side of the first electrode S and the second electrode D away from the inter-layer dielectric layer ILD; a pixel definition layer PDL defining a subpixel aperture and on a side of the planarization layer PLN away from the base substrate BS; and a light emitting element LE in the subpixel aperture. The light emitting element LE includes an anode AD on a side of the planarization layer PLN away from the inter-layer dielectric layer ILD; a light emitting layer EL on a side of the anode AD away from the planarization layer PLN; and a cathode layer CD on a side of the light emitting layer EL away from the anode AD. The display panel in the display region further includes an encapsulating layer EN encapsulating the light emitting element LE, and on a side of the cathode layer CD away from the base substrate BS. The encapsulating layer EN in some embodiments includes a first inorganic encapsulating sub-layer CVD1 on a side of the cathode layer CD away from the base substrate BS, an organic encapsulating sub-layer IJP on a side of the first inorganic encapsulating sub-layer CVD1 away from the base substrate BS, and a second inorganic encapsulating sub-layer CVD2 on a side of the organic encapsulating sub-layer IJP away from the first inorganic encapsulating sub-layer CVD1. The display panel in the display region further includes a buffer layer BUF on a side of the encapsulating layer EN away from the base substrate BS; a plurality of second electrode bridges BR2 on a side of the buffer layer BUF away from the encapsulating layer EN; a touch insulating layer TI on a side of the plurality of second electrode bridges BR2 away from the buffer layer BUF; a plurality of first touch electrodes TE1 on a side of the touch insulating layer TI away from the buffer layer BUF; and an overcoat layer OC on a side of the plurality of first touch electrodes TE1 away from the touch insulating layer TI.

Referring to FIG. 6A, the display panel includes a semiconductor material layer SML, a first conductive layer Gate1, a second conductive layer Gate2, and a first signal line layer SLL1. The display panel further includes an insulating layer IN between the first conductive layer Gate1 and the second conductive layer Gate2; and an inter-layer dielectric layer ILD between the second conductive layer Gate2 and the first signal line layer SLL1.

FIG. 6B illustrates a detailed structure in a display region in a display panel in some embodiments according to the present disclosure. Referring to FIG. 6B, the display panel in the display region in some embodiments includes a base substrate BS (e.g., a flexible base substrate); an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first conductive layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second conductive layer) on a side of the insulating layer IN away from the gate insulating layer GI; an inter-layer dielectric layer ILD on a side of the second capacitor electrode Ce2 away from the gate insulating layer GI; a first electrode S and a second electrode D (parts of a first SD metal layer) on a side of the inter-layer dielectric layer ILD away from the gate insulating layer GI; a passivation layer PVX on a side of the first electrode S and the second electrode D away from the inter-layer dielectric layer ILD; a first planarization layer PLN1 on a side of the passivation layer PVX away from the inter-layer dielectric layer ILD; a relay electrode RE (part of a second SD metal layer) on a side of the first planarization layer PLN1 away from the passivation layer PVX; a second planarization layer PLN2 on side of the relay electrode RE away from the first planarization layer PLN1; a pixel definition layer PDL defining a subpixel aperture and on a side of the second planarization layer PLN2 away from the base substrate BS; and a light emitting element LE in the subpixel aperture. The light emitting element LE includes an anode AD on a side of the second planarization layer PLN2 away from the first planarization layer PLN1; a light emitting layer EL on a side of the anode AD away from the second planarization layer PLN2; and a cathode layer CD on a side of the light emitting layer EL away from the anode AD. The display panel in the display region further includes an encapsulating layer EN encapsulating the light emitting element LE, and on a side of the cathode layer CD away from the base substrate BS. The encapsulating layer EN in some embodiments includes a first inorganic encapsulating sub-layer CVD1 on a side of the cathode layer CD away from the base substrate BS, an organic encapsulating sub-layer IJP on a side of the first inorganic encapsulating sub-layer CVD1 away from the base substrate BS, and a second inorganic encapsulating sub-layer CVD2 on a side of the organic encapsulating sub-layer IJP away from the first inorganic encapsulating sub-layer CVD1. The display panel in the display region further includes a buffer layer BUF on a side of the encapsulating layer EN away from the base substrate BS; a plurality of second electrode bridges BR2 on a side of the buffer layer BUF away from the encapsulating layer EN; a touch insulating layer TI on a side of the plurality of second electrode bridges BR2 away from the buffer layer BUF; a plurality of first touch electrodes TE1 on a side of the touch insulating layer TI away from the buffer layer BUF; and an overcoat layer OC on a side of the plurality of first touch electrodes TE1 away from the touch insulating layer TI. Optionally, the display panel in the display region does not include the passivation layer PVX, e.g., the inter-layer dielectric layer ILD is in direct contact with the first planarization layer PLN1.

Referring to FIG. 6B, the display panel includes a semiconductor material layer SML, a first conductive layer Gate1, a second conductive layer Gate2, a first signal line layer SLL1, and a second signal line layer SLL2. The display panel further includes an insulating layer IN between the first conductive layer Gate1 and the second conductive layer Gate2; an inter-layer dielectric layer ILD between the second conductive layer Gate2 and the first signal line layer SLL1; and at least a passivation layer PVX or a planarization layer PLN between the first signal line layer SLL1 and the second signal line layer SLL2.

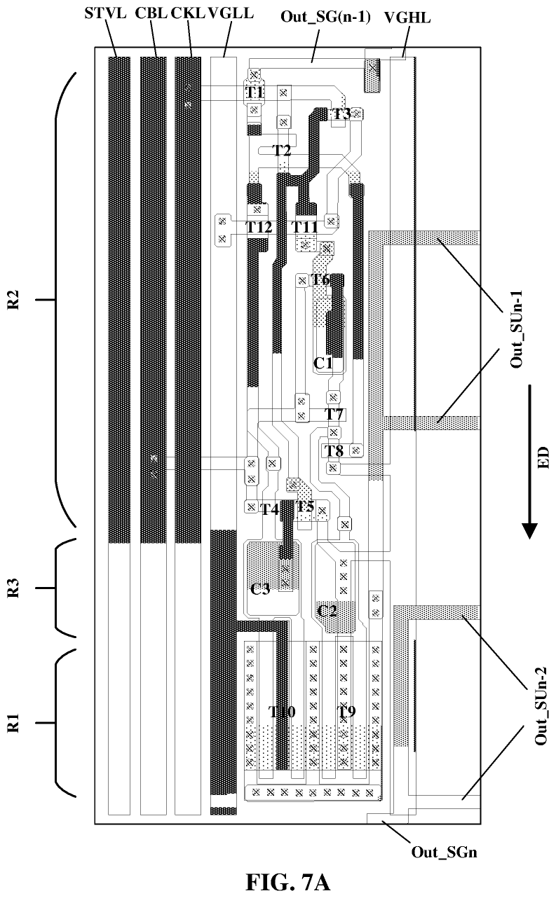

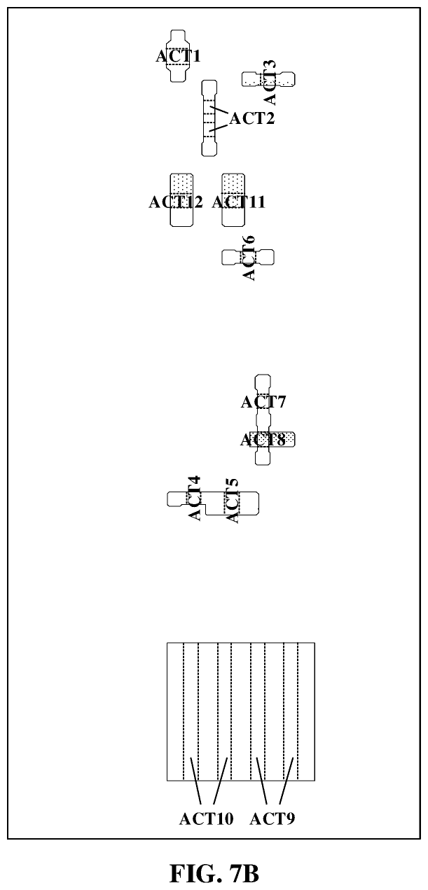

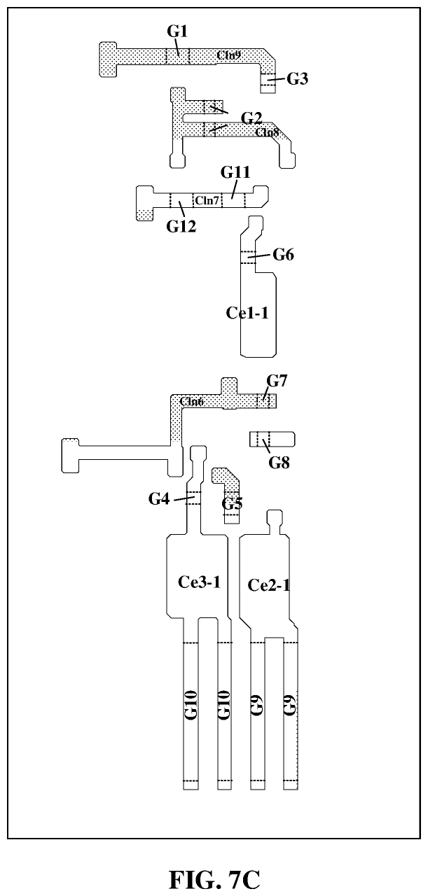

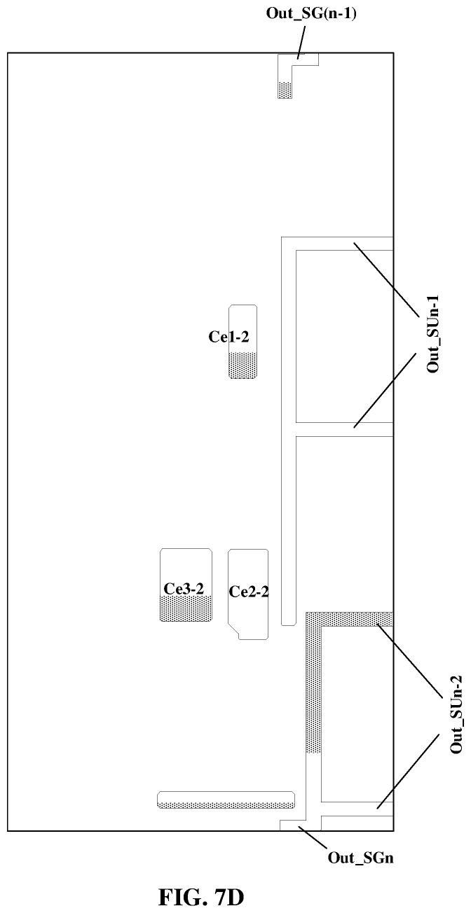

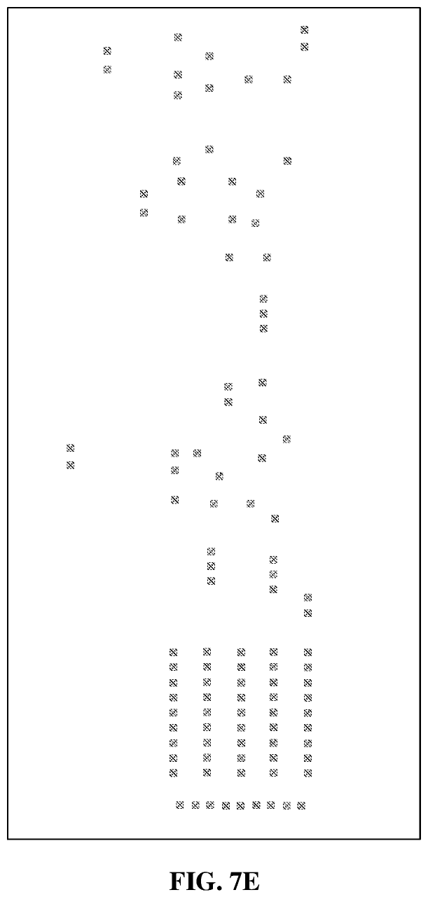

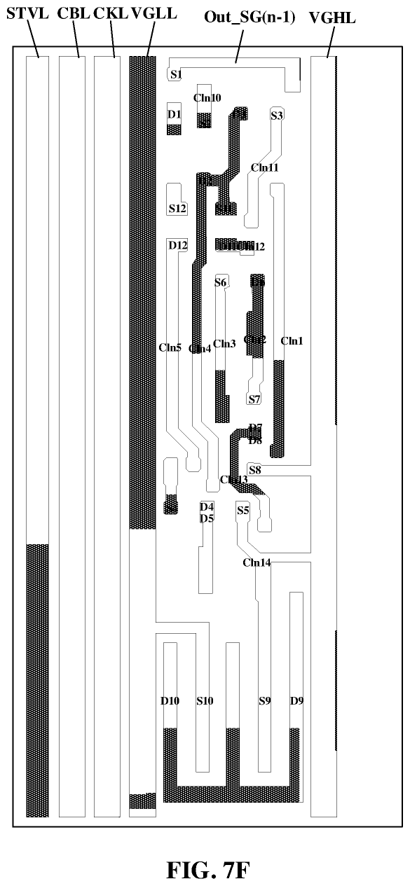

FIG. 7A illustrates the structure of a first n-th stage scan unit in some embodiments according to the present disclosure. FIG. 7B illustrates the structure of a semiconductor material layer in the first n-th stage scan unit depicted in FIG. 7A. FIG. 7C illustrates the structure of a first conductive layer in the first n-th stage scan unit depicted in FIG. 7A. FIG. 7D illustrates the structure of a second conductive layer in the first n-th stage scan unit depicted in FIG. 7A. FIG. 7E illustrates the structure of an inter-layer dielectric layer in the first n-th stage scan unit depicted in FIG. 7A. FIG. 7F illustrates the structure of a first signal line layer in the first n-th stage scan unit depicted in FIG. 7A. FIG. 7A to FIG. 7F correspond to a first n-th stage scan unit SUn-1 depicted in FIG. 1A to FIG. 3. The positions of the transistors T1 to T12, and the capacitors C1 to C3 are annotated in FIG. 7A.

Referring to FIG. 7B, the semiconductor material layer (e.g., corresponding to SML in FIG. 4A to FIG. 4B) includes active layers of the transistors in the first n-th stage scan unit. Active layers of the transistors are annotated in FIG. 7B. Referring to FIG. 7A and FIG. 7B, in some embodiments, the active layer ACT1 of the first transistor T1, the active layer ACT2 of the second transistor T2, the active layer ACT3 of the third transistor T3, the active layer ACT4 of the fourth transistor T4, the active layer ACT5 of the fifth transistor T5, the active layer ACT6 of the sixth transistor T6, the active layer ACT7 of the seventh transistor T7, the active layer ACT8 of the eighth transistor T8, the active layer ACT9 of the ninth transistor T9, the active layer ACT10 of the tenth transistor T10, the active layer ACT11 of the eleventh transistor T11, and the active layer ACT12 of the twelfth transistor T12, are in a same layer. In one example, the second transistor T2 is a double gate transistor, and the active layer ACT2 of the second transistor T2 includes two portions spaced apart from each other, as depicted in FIG. 7B. In another example, the ninth transistor T9 is a multi-gate transistor, and the active layer ACT9 of the ninth transistor T9 includes multiple portions spaced apart from each other, as depicted in FIG. 7B. In another example, the tenth transistor T10 is a multi-gate transistor, and the active layer ACT10 of the tenth transistor T10 includes multiple portions spaced apart from each other, as depicted in FIG. 7B.

As used herein, the term “same layer” refers to the relationship between the layers simultaneously formed in the same step. In one example, the active layers of transistors are in a same layer when they are formed as a result of one or more steps of a same patterning process performed in a same layer of material. In another example, the active layers can be formed in a same layer by simultaneously performing the step of forming a first active layer, and the step of forming a second active layer. The term “same layer” does not always mean that the thickness of the layer or the height of the layer in a cross-sectional view is the same.

As used herein, the active layer refers to a component of the transistor comprising at least a portion of the semiconductor material layer whose orthographic projection on the base substrate overlaps with an orthographic projection of a gate electrode on the base substrate. As used herein, a first electrode refers to a component of the transistor connected to one side of the active layer, and a second electrode refers to a component of the transistor connected to another side of the active layer. In the context of a double-gate type transistor (for example, the second transistor T2), the active layer refers to a component of the transistor comprising a first portion of the semiconductor material layer whose orthographic projection on the base substrate overlaps with an orthographic projection of a first gate on the base substrate, a second portion of the semiconductor material layer whose orthographic projection on the base substrate overlaps with an orthographic projection of a second gate on the base substrate, and a third portion between the first portion and the second portion. In the context of a double-gate type transistor, a first electrode refers to a component of the transistor connected to a side of the first portion distal to the third portion, and a second electrode refers to a component of the transistor connected to a side of the second portion distal to the third portion.

Referring to FIG. 7C, the first conductive layer (e.g., corresponding to Gate1 in FIG. 4A to FIG. 4B) in some embodiments includes gate electrodes of transistor in the first n-th stage scan unit. Gate electrodes of the transistors are annotated in FIG. 7C. Referring to FIG. 7A and FIG. 7C, in some embodiments, the gate electrode G1 of the first transistor T1, the gate electrode G2 of the second transistor T2, the gate electrode G3 of the third transistor T3, the gate electrode G4 of the fourth transistor T4, the gate electrode G5 of the fifth transistor T5, the gate electrode G6 of the sixth transistor T6, the gate electrode G7 of the seventh transistor T7, the gate electrode G8 of the eighth transistor T8, the gate electrode G9 of the ninth transistor T9, the gate electrode G10 of the tenth transistor T10, the gate electrode G11 of the eleventh transistor T11, and the gate electrode G12 of the twelfth transistor T12, are in a same layer. In one example, the second transistor T2 is a double gate transistor, and the gate electrode G2 of the second transistor T2 includes two portions spaced apart from each other, as depicted in FIG. 7C. In another example, the ninth transistor T9 is a multi-gate transistor, and the gate electrode G9 of the ninth transistor T9 includes multiple portions spaced apart from each other, as depicted in FIG. 7C. In another example, the tenth transistor T10 is a multi-gate transistor, and the gate electrode G10 of the tenth transistor T10 includes multiple portions spaced apart from each other, as depicted in FIG. 7C. Optionally, the gate electrode G1 of the first transistor T1 and the gate electrode G3 of the third transistor T3 are parts of a unitary structure. Optionally, the gate electrode G11 of the eleventh transistor T11 and the gate electrode G12 of the twelfth transistor T12 are parts of a unitary structure.

In some embodiments, the first conductive layer further includes first capacitor electrodes of capacitors in the first n-th stage scan unit. First capacitor electrodes of capacitors are annotated in FIG. 7C. Referring to FIG. 7A and FIG. 7C, in some embodiments, a first capacitor electrode Ce1-1 of the first capacitor C1, a first capacitor electrode Ce2-1 of the second capacitor C2, a first capacitor electrode Ce3-1 of the third capacitor C3, are in a same layer. Optionally, the first capacitor electrode Ce1-1 of the first capacitor C1 and the gate electrode G6 of the sixth transistor T6 are parts of a unitary structure. Optionally, the first capacitor electrode Ce2-1 of the second capacitor C2, the gate electrode G9 of the ninth transistor T9 are parts of a unitary structure. Optionally, the first capacitor electrode Ce3-1 of the third capacitor C3, the gate electrode G4 of the fourth transistor T4, and the gate electrode G10 of the tenth transistor T10, are parts of a unitary structure.

Referring to FIG. 7D, the second conductive layer (e.g., corresponding to Gate2 in FIG. 4A to FIG. 4B) includes second capacitor electrodes of capacitors in the first n-th stage scan unit. Second capacitor electrodes of capacitors are annotated in FIG. 7D. Referring to FIG. 7A and FIG. 7D, in some embodiments, a second capacitor electrode Ce1-2 of the first capacitor C1, a second capacitor electrode Ce2-2 of the second capacitor C2, a second capacitor electrode Ce3-2 of the third capacitor C3, are in a same layer. The second conductive layer in some embodiments further includes an input signal line configured to receive an output signal Out_SG(n-1) from the (n−1)-th stage SG(n-1) as input; an output signal line configured to output an output signal Out_SUn-1 from the first n-th stage scan unit SUn-1 to the m1 number of rows of the M rows of subpixels as control signals therein, and subsequently input to the second n-th stage scan unit SUn-2 as an input signal thereof; an output signal line configured to transmit an output signal Out_SUn-2 from the second n-th stage scan unit SUn-2, subsequent to that the output signal Out_SUn-2 being provided to the m2 number of rows of the M rows of subpixels. The output signal from the n-th stage SGn of the scan circuit is denoted by an output signal Out_SGn, which is used as an input signal in the (n+1)-th stage of the scan circuit.

Referring to FIG. 7A to FIG. 7E, the output signal line configured to output an output signal Out_SUn-1 from the first n-th stage scan unit SUn-1 is electrically connected to second electrodes of the ninth transistor T9 and the tenth transistor T10.

In some embodiments, referring to FIG. 1A, and FIG. 7A to FIG. 7E, all of the m1 number of output branch lines are electrically connected to second electrodes of the ninth transistor T9 and the tenth transistor T10 of the first n-th stage scan unit, and electrically connected to an input signal line of the second n-th stage scan unit

Referring to FIG. 7F, the first signal line layer (e.g., corresponding to SLL1 in FIG. 4A to FIG. 4B) includes first electrodes and second electrodes of transistors in the first n-th stage scan unit. Referring to FIG. 7A and FIG. 7F, in some embodiments, the first electrode S1 of the first transistor T1, the first electrode S2 of the second transistor T2, the first electrode S3 of the third transistor T3, the first electrode S4 of the fourth transistor T4, the first electrode S5 of the fifth transistor T5, the first electrode S6 of the sixth transistor T6, the first electrode S7 of the seventh transistor T7, the first electrode S8 of the eighth transistor T8, the first electrode S9 of the ninth transistor T9, the first electrode S10 of the tenth transistor T10, the first electrode S11 of the eleventh transistor T11, the first electrode S12 of the twelfth transistor T12, the second electrode D1 of the first transistor T1, the second electrode D2 of the second transistor T2, the second electrode D3 of the third transistor T3, the second electrode D4 of the fourth transistor T4, the second electrode D5 of the fifth transistor T5, the second electrode D6 of the sixth transistor T6, the second electrode D7 of the seventh transistor T7, the second electrode D8 of the eighth transistor T8, the second electrode D9 of the ninth transistor T9, the second electrode D10 of the tenth transistor T10, the second electrode D11 of the eleventh transistor T11, and the second electrode D12 of the twelfth transistor T12, are in a same layer.

In some embodiments, the first signal line layer further includes a first clock signal line CKL configured to provide a first clock signal, a second clock signal line CBL configured to provide a second clock signal, a first power supply signal line VGHL configured to provide a first power supply signal, a second power supply signal line VGLL configured to provide a second power supply signal, and a start signal line STVL configured to provide a start signal.

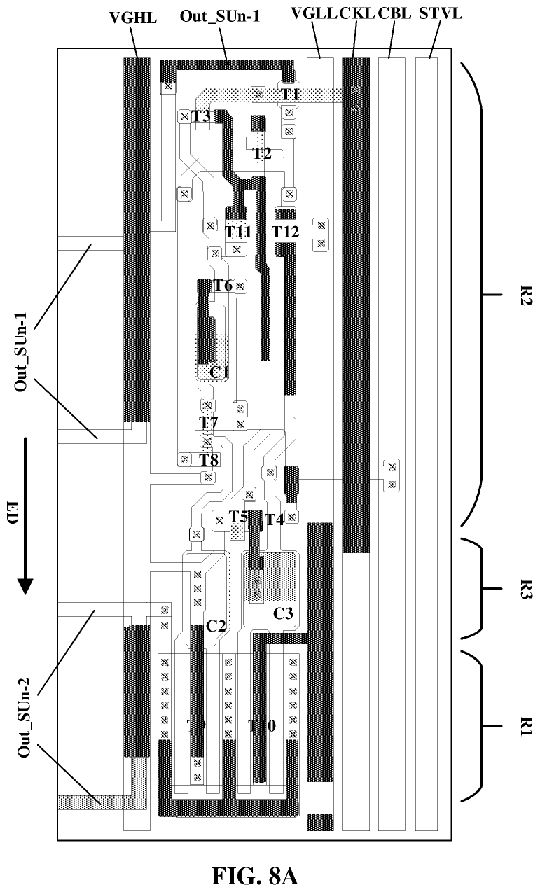

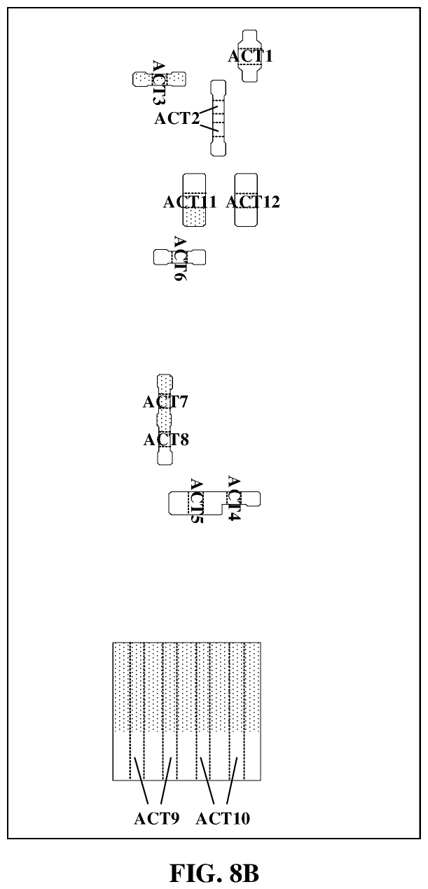

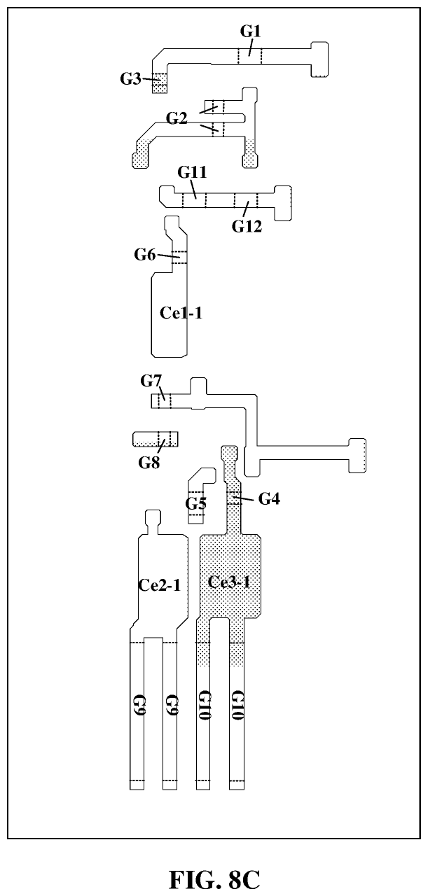

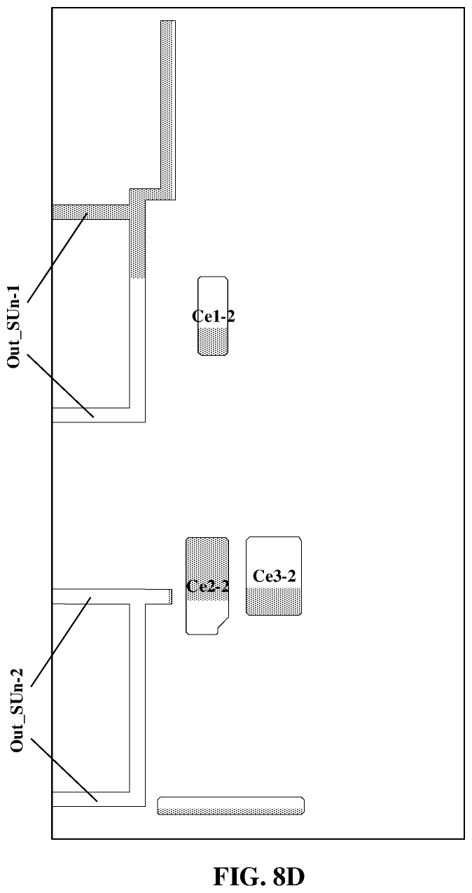

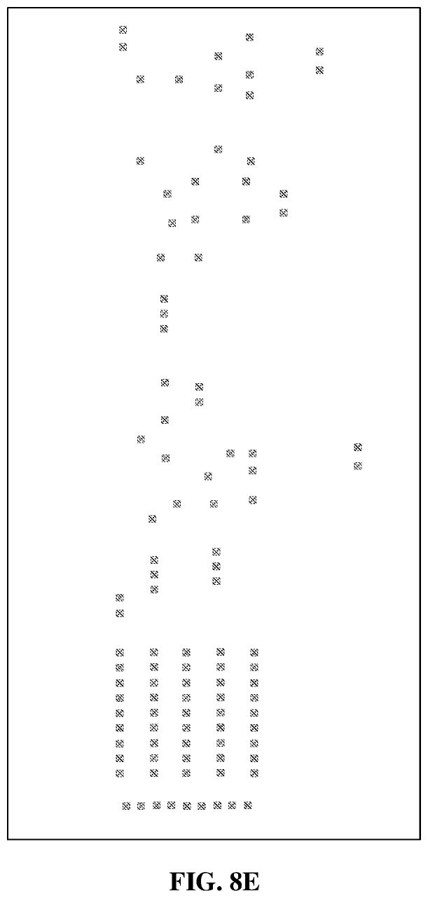

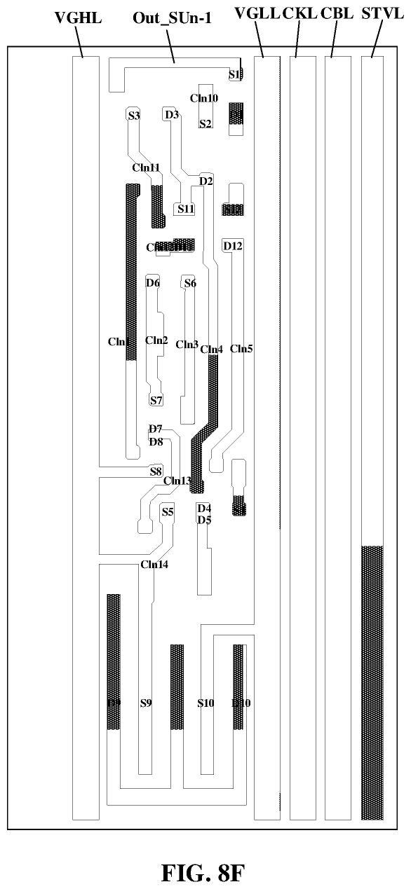

FIG. 8A illustrates the structure of a second n-th stage scan unit in some embodiments according to the present disclosure. FIG. 8B illustrates the structure of a semiconductor material layer in the second n-th stage scan unit depicted in FIG. 8A. FIG. 8C illustrates the structure of a first conductive layer in the second n-th stage scan unit depicted in FIG. 8A. FIG. 8D illustrates the structure of a second conductive layer in the second n-th stage scan unit depicted in FIG. 8A. FIG. 8E illustrates the structure of an inter-layer dielectric layer in the second n-th stage scan unit depicted in FIG. 8A. FIG. 8F illustrates the structure of a first signal line layer in the second n-th stage scan unit depicted in FIG. 8A. FIG. 8A to FIG. 8F correspond to a second n-th stage scan unit SUn-2 depicted in FIG. 1A to FIG. 3. The positions of the transistors T1 to T12, and the capacitors C1 to C3 are annotated in FIG. 8A. The structures of various layers of the second n-th stage scan unit depicted in FIG. 8A to FIG. 8F are largely similar to corresponding structures of various layers of the first n-th stage scan unit depicted in FIG. 7A to FIG. 7F. One of the distinctions between the structure of the first n-th stage scan unit and the structure of the second n-th stage scan unit resides in that the first n-th stage scan unit has an input signal line that is configured to receive an output signal Out_SG(n-1) from the (n−1)-th stage SG(n-1) as input, whereas the second n-th stage scan unit has an input signal line that is configured to receive an output signal Out_SUn-1 from the first n-th stage scan unit SUn-1 as input. Another distinction resides in that the first n-th stage scan unit has an output signal line configured to output an output signal Out_SUn-1 from the first n-th stage scan unit SUn-1 to the m1 number of rows of the M rows of subpixels as control signals therein, and subsequently input to the second n-th stage scan unit SUn-2 as an input signal thereof, whereas the second n-th stage scan unit has an output signal line configured to output an output signal Out_SUn-2 from the second n-th stage scan unit SUn-2 to the m2 number of rows of the M rows of subpixels, and subsequently input to the (n+1)-th stage of the scan circuit.

Referring to FIG. 8D, the second conductive layer (e.g., corresponding to Gate2 in FIG. 4A to FIG. 4B) includes second capacitor electrodes of capacitors in the second n-th stage scan unit. The second conductive layer of the second n-th stage scan unit SUn-2 in some embodiments further includes an input signal line configured to receive an output signal Out SUn-1 from the first n-th stage scan unit SUn-1, subsequent to that the output signal Out_SUn-1 being provided to the m1 number of rows of the M rows of subpixels as control signals therein; and an output signal line configured to output an output signal Out_SUn-2 to the (n+1)-th stage of the scan circuit, subsequent to that the output signal Out_SUn-2 being provided to the m2 number of rows of the M rows of subpixels.

Referring to FIG. 8A to FIG. 8E, the output signal line configured to output an output signal Out_SUn-2 from the second n-th stage scan unit SUn-2 is electrically connected to second electrodes of the ninth transistor T9 and the tenth transistor T10 in the second n-th stage scan unit SUn-2.

In some embodiments, referring to FIG. 1A, and FIG. 8A to FIG. 8E, all of the m2 number of output branch lines are electrically connected to second electrodes of a ninth transistor T9 and a tenth transistor T10 of the second n-th stage scan unit, and electrically connected to an input signal line of the (n+1)-th stage of the scan circuit.

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor, in one example, the first electrode is configured to receive an input signal and the second electrode is configured to output an output signal; in another example, the second electrode is configured to receive an input signal and the first electrode is configured to output an output signal.

As discussed above, in the present scan circuit, a length of the first scan unit along a column direction spans over the M rows of subpixels; and a length of the second scan unit along the column direction spans over the same M rows of subpixels. To accommodate this unique arrangement, the layout of the respective scan unit adopts a unique structure. Referring to FIG. 7A and FIG. 8A, in some embodiments, all transistors and all capacitors of a respective scan unit of the two scan units are arranged in a region between the first voltage supply line VGHL and the second voltage supply line VGLL.

In some embodiments, the ninth transistor T9 and the tenth transistor T10 are in a first region R1, transistors other than the ninth transistor T9 and the tenth transistor T10 are in a second region R2, the first region R1 and the second region R2 are sequentially arranged along extension directions ED of the first voltage supply line VGHL and the second voltage supply line VGLL. Optionally, the extension directions ED of the first voltage supply line VGHL and the second voltage supply line VGLL are parallel to a column direction of a display panel having a plurality of rows of subpixels. The first region 1I and the second region R2 are non-overlapping regions.

In some embodiments, the second capacitor C2 and the third capacitor C3 are in a third region R3. The first region R1, the third region R3, and the second region R2 are sequentially arranged along the extension directions ED of the first voltage supply line VGHL and the second voltage supply line VGLL. The first region R1, the third region R3, and the second region R2 are non-overlapping regions.

Referring to FIG. 7A to FIG. 7F, and FIG. 8A to FIG. 8F, in some embodiments, the first signal line layer includes a first voltage supply line VGHL, a second voltage supply line VGLL, a first connecting line Cln1, a second connecting line Cln2, a third connecting line Cln3, a fourth connecting line Cln4, and a fifth connecting line Cln5 in a same layer. In some embodiments, at least portions of the first connecting line Cln1, the second connecting line Cln2, the third connecting line Cln3, the fourth connecting line Cln4, and the fifth connecting line Cln5 are substantially parallel to extension directions of the first voltage supply line VGHL and the second voltage supply line VGLL. As used herein, the term “substantially parallel” means that an angle is in the range of 0 degree to approximately 30 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

In some embodiments, the first connecting line Cln1 electrically connects gate electrodes of a second transistor T2 and an eighth transistor T8. For example, the first connecting line Cln1 extends through vias extending through the inter-layer dielectric layer and the insulating layer to connect to the first conductive layer, in which the gate electrodes of the second transistor T2 and the eighth transistor T8 are disposed.

In some embodiments, the second connecting line Cln2 electrically connects a second electrode D6 of a sixth transistor T6 with a first electrode S7 of a seventh transistor T7, and is connected to a second capacitor electrode Ce1-2 of a first capacitor C1 through one or more vias extending through an inter-layer dielectric layer. An orthographic projection of the second connecting line Cln2 on a base substrate at least partially overlaps with an orthographic projection of the second capacitor electrode Ce1-2 of the first capacitor C1 on the base substrate. Optionally, longitudinal directions of the first capacitor electrode Ce1-1 and the second capacitor electrode Ce1-2 of the first capacitor C1 are substantially parallel to the extension directions ED.

In some embodiments, the third connecting line Cln3 electrically connects a first electrode S6 of the sixth transistor T6 with a gate electrode G7 of the seventh transistor T7. For example, the third connecting line Cln3 extends through one or more vias extending through the inter-layer dielectric layer and the insulating layer to connect to the first conductive layer, in which the gate electrode G7 of the seventh transistor T7 is disposed.

In some embodiments, the fourth connecting line Cln4 electrically connects a gate electrode G5 of a fifth transistor T5, a second electrode D2 of a second transistor T2, a first electrode S11 of an eleventh transistor T11, and a second electrode D3 of a third transistor T3 together. For example, the fourth connecting line Cln4 extends through one or more vias extending through the inter-layer dielectric layer and the insulating layer to connect to the first conductive layer, in which the gate electrode G5 of the fifth transistor T5 is disposed.

In some embodiments, the fifth connecting line Cln5 electrically connects a gate electrode G4 of a fourth transistor T4 with a second electrode D12 of a twelfth transistor T12. For example, the fifth connecting line Cln5 extends through one or more vias extending through the inter-layer dielectric layer and the insulating layer to connect to the first conductive layer, in which the gate electrode G4 of the fourth transistor T4 is disposed.

Referring to FIG. 7A to FIG. 7F, and FIG. 8A to FIG. 8F, in some embodiments, the first conductive layer includes a sixth connecting line Cln6, a seventh connecting line Cln7, an eighth connecting line Cln8, and a ninth connecting line Cln9.

In some embodiments, the sixth connecting line Cln6 electrically connects a second clock signal line CBL with gate electrodes of a fourth transistor T4, a fifth transistor T5, and a seventh transistor T7. Optionally, the sixth connecting line Cln6 crosses over the fourth connecting line Cln4 and the fifth connecting line Cln5, and is connected to the third connecting line Cln3 through one or more vias extending through an insulating layer and an inter-layer dielectric layer.

In some embodiments, the seventh connecting line Cln7 electrically connects a second voltage supply line VGLL with gate electrodes of an eleventh transistor T11 and a twelfth transistor T12. Optionally, the seventh connecting line Cln7 crosses over the fourth connecting line Cln4.

In some embodiments, the eighth connecting line Cln8 electrically connects a gate electrode G2 of a second transistor T2 with the first connecting line Cln1, a second electrode D1 of a first transistor T1, and a first electrode S12 of a twelfth transistor T12. Optionally, the eighth connecting line Cln8 crosses over the fourth connecting line Cln4.

In some embodiments, the ninth connecting line Cln9 electrically connects a first clock signal line CKL with gate electrodes of a first transistor T1 and a third transistor T3.

Referring to FIG. 7A to FIG. 7F, and FIG. 8A to FIG. 8F, in some embodiments, the first signal line layer further includes a tenth connecting line Cln10, an eleventh connecting line Cln11, a twelfth connecting line Cln12, a thirteenth connecting line Cln13, and a fourteenth connecting line Cln14.

In some embodiments, the tenth connecting line Cln10 electrically connects a first electrode S2 of the second transistor T2 with the ninth connecting line Cln9, which electrically connects a first clock signal line CKL with gate electrodes of a first transistor T1 and a third transistor T3.

In some embodiments, the eleventh connecting line Cln11 electrically connects a first electrode S3 of a third transistor T3 with the seventh connecting line Cln7, which electrically connects a second voltage supply line VGLL with gate electrodes of an eleventh transistor T11 and a twelfth transistor T12.

In some embodiments, the twelfth connecting line Cln12 electrically connects a second electrode D12 of a twelfth transistor T12 with a gate electrode G6 of a sixth transistor T6. For example, the twelfth connecting line Cln12 extends through one or more vias extending through the inter-layer dielectric layer and the insulating layer to connect with the first conductive layer, in which the gate electrode G6 of the sixth transistor T6 is disposed.

In some embodiments, the thirteenth connecting line Cln13 electrically connects second electrodes of a seventh transistor T7 and an eighth transistor T8 to a first capacitor electrode Ce2-1 of the second capacitor C2.

In some embodiments, the fourteenth connecting line Cln14 electrically connects a first electrode S5 of a fifth transistor T5 with a first electrode S9 of a ninth transistor T9 and the first voltage supply line VGHL.

Referring to FIG. 7A to FIG. 7F, and FIG. 8A to FIG. 8F, in some embodiments, the first gate layer, the second gate layer, the first conductive layer, and the first signal line layer in the first scan unit and in the second scan unit have a mirror symmetry.

Referring to FIG. 7A to FIG. 7F, and FIG. 8A to FIG. 8F, in some embodiments, the second conductive layer in the first scan unit and in the second scan unit have a mirror symmetry except for output signal lines therein.

In another aspect, the present invention provides a display apparatus, including the scan circuit described herein or fabricated by a method described herein, and a display panel having a plurality of light emitting elements. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus. Optionally, the display apparatus is a quantum dots display apparatus.

The scan circuit described in the present disclosure may be used for generating various appropriate control signals to subpixels in a display panel. In one example, the scan circuit described in the present disclosure is a light emitting control signal generating circuit configured to generate light emitting control signals for subpixels in a display panel. In another example, the scan circuit described in the present disclosure is a gate scanning signal generating circuit configured to generate gate scanning signals for subpixels in a display panel. In another example, the scan circuit described in the present disclosure is a reset control signal generating circuit configured to generate reset control signals for subpixels in a display panel.

In some embodiments, the scan circuit described in the present disclosure is a light emitting control signal generating circuit configured to generate light emitting control signals for subpixels in a display panel. Optionally, the display apparatus further includes a gate scanning signal generating circuit and a reset control signal generating circuit separate from each other.

In the present display apparatus having the present scan circuit (e.g., as the light emitting control signal generating circuit), the peripheral area of the display apparatus may be made much smaller as compared to related display apparatuses. In one example, a width of at least one side of the peripheral area of the display apparatus may be reduced by 70 μm. In another example, the peripheral area of the display apparatus may be reduced by 15%. The present display apparatus has a significantly increased display region.

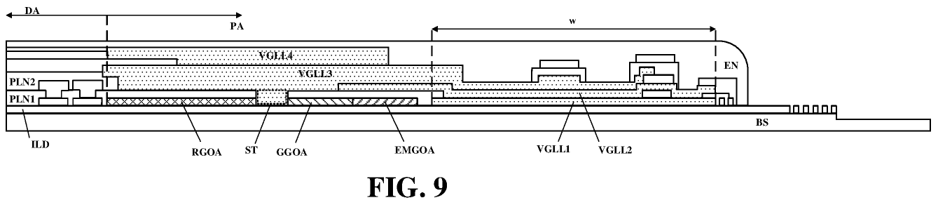

FIG. 9 is a schematic diagram illustrating the structure of a peripheral area of a display apparatus in some embodiments according to the present disclosure. Referring to FIG. 9, the display apparatus in the peripheral area includes a base substrate BS, an inter-layer dielectric layer ILD on the base substrate BS, a first planarization layer PLN1 on a side of the inter-layer dielectric layer ILD away from the base substrate BS, and a second planarization layer PLN2 on a side of the first planarization layer PLN1 away from the inter-layer dielectric layer ILD. The display apparatus includes a light emitting control signal generating circuit EMGOA, a gate scanning signal generating circuit GGOA, and a reset control signal generating circuit RGOA in the peripheral area. The gate scanning signal generating circuit GGOA and the reset control signal generating circuit RGOA are separate from each other. In some embodiments, the second voltage supply signal line includes four sublayers, including a first sub-layer VGLL1, a second sub-layer VGLL2 on the first sub-layer VGLL1, a third sub-layer VGLL3 on a side of the second sub-layer VGLL2 away from the first sub-layer VGLL1, and a fourth sub-layer VGLL4 on a side of the third sub-layer VGLL3 away from the second sub-layer VGLL2. In one example, the third sub-layer VGLL3 is in a same layer as an anode layer of light emitting diodes in the display apparatus. In another example, the fourth sub-layer VGLL4 is in a same layer as a cathode layer of light emitting diodes in the display apparatus. The display apparatus further includes an encapsulating layer EN on a side of the fourth sub-layer VGLL4 away from the base substrate BS, thereby encapsulating the display apparatus. As shown in FIG. 9, the first sub-layer VGLL1 has a width w along a direction from the display region DA to the peripheral area PA.

In some embodiments, the third sub-layer VGLL3 extends through a slot ST extending through at least the first planarization layer PLN1. A portion of the third sub-layer VGLL3 in the slot ST spaces apart the reset control signal generating circuit RGOA and the gate scanning signal generating circuit GGOA. The light emitting control signal generating circuit EMGOA is on a side of the gate scanning signal generating circuit GGOA away from the slot ST and the reset control signal generating circuit RGOA.

The inventors of the present disclosure, surprisingly and unexpectedly, the present display apparatus having the scan circuit, particularly when the scan circuit is used as the light emitting control signal generating circuit EMGOA, has superior display qualities. Table 1 lists several related display apparatuses and a display apparatus according to the present disclosure.

TABLE 1
Parameters associated with several related display apparatuses
and a display apparatus according to the present disclosure.

| | Channel | | | | |
|---|---|---|---|---|---|
| | width of a | Channel | Channel | | |
| | fourth | width of a | width of a | Channel | |
| | transistor in | fourth | fifth transistor | width of a | |
| | the gate | transistor in | in the gate | fifth transistor | |
| | scanning | the reset | scanning | in the reset | |
| | signal | control signal | signal | control signal | A width w of |
| | generating | generating | generating | generating | the first sub- |
| Display | circuit GGOA | circuit RGOA | circuit GGOA | circuit RGOA | layer VGLL1 |
| apparatus | (μm) | (μm) | (μm) | (μm) | (μm) |
| A | L: 40 | L: 40 | L: 120 | L: 120 | L: 600 |
| | R: 60 | R: 60 | R: 180 | R: 180 | R: 367 |
| B | 150 | 150 | 450 | 450 | 460 |
| C | 45 | 15 | 135 | 45 | 460 |
| D | 78.75 | 26.25 | 236.25 | 78.75 | 460 |
| E | 78.75 | 26.25 | 236.25 | 78.75 | 460 |
| F | 123.75 | 41.25 | 371.25 | 123.75 | 400 |
| G | 105 | 35 | 315 | 105 | 460 |
| H | 150 | 50 | 450 | 150 | 400 |

In display apparatus A, L denotes a left side of the display apparatus, while R denotes a right side of the display apparatus. The left side includes a gate scanning signal generating circuit GGOA and a reset control signal generating circuit RGOA, while the right side includes a gate scanning signal generating circuit GGOA, a reset control signal generating circuit RGOA, and a light emitting control signal generating circuit EMGOA. In display apparatus A, one stage of the light emitting control signal generating circuit EMGOA (on the right side) is configured to provide light emitting control signals to only one row of subpixels.

In display apparatus B and display apparatus C, each stage of the light emitting control signal generating circuit EMGOA includes one scan unit on the left side and another scan unit on the right side. Each stage is configured to provide light emitting control signals to only one row of subpixels.

In display apparatus D, each stage of the light emitting control signal generating circuit EMGOA is configured to provide light emitting control signals to only one row of subpixels. Each stage includes only one scan unit. Scan units of the light emitting control signal generating circuit EMGOA are alternately on the left side and the right side.

In display apparatus E and display apparatus F, each stage of the light emitting control signal generating circuit EMGOA is configured to provide light emitting control signals to two rows of subpixels. Each stage includes one scan unit on the left side and another scan unit on the right side.

Display apparatuses G and H include a light emitting control signal generating circuit EMGOA according to the present disclosure. In the display apparatus G and display apparatus H, each stage of the light emitting control signal generating circuit EMGOA includes one scan unit on the left side and another scan unit on the right side. The scan unit on the left side is configured to provide light emitting control signals to two rows of subpixels, and the scan unit on the right side is configured to provide light emitting control signals to another two rows of subpixels, as depicted in FIG. 1A. Comparing the display apparatus G with display apparatus H, the width w of the first sub-layer VGLL1 in the display apparatus H is further reduced as compared to the display apparatus G.

In the display apparatus A and display apparatus B, channel widths of the fourth transistors in the gate scanning signal generating circuit GGOA and in the reset control signal generating circuit RGOA are the same; channel widths of the fifth transistors in the gate scanning signal generating circuit GGOA and in the reset control signal generating circuit RGOA are the same. Channel widths of the fifth transistors is three times of channel widths of the fourth transistors in the gate scanning signal generating circuit GGOA or in the reset control signal generating circuit RGOA.

In the display apparatuses C to H, channel widths of the fifth transistors is three times of channel widths of the fourth transistors in the gate scanning signal generating circuit GGOA or in the reset control signal generating circuit RGOA. The channel width of the fourth transistor in the gate scanning signal generating circuit GGOA is three times of the channel width of the fourth transistor in reset control signal generating circuit RGOA. The channel width of the fifth transistor in the gate scanning signal generating circuit GGOA is three times of the channel width of the fifth transistor in reset control signal generating circuit RGOA.

As compared to the related display apparatuses, the display apparatus according to the present disclosure generates light emitting control signals with highest stability. Table 2 and Table 3 show results of signal stability generated by several related display apparatuses and a display apparatus according to the present disclosure.

Table 2. Signal stability generated by several related display apparatuses and a display apparatus according to the present disclosure.

| | | Product | | | | | |
|---|---|---|---|---|---|---|---|
| | | B | C | E | F | G | H |
| RGOA | Tr (ns) | 718 | 886 | 748 | 653 | 683 | 626 |
| | Tf(ns) | 811 | 1318 | 942 | 757 | 808 | 715 |
| GGOA | Tr (ns) | 769 | 738 | 698 | 665 | 676 | 655 |
| | Tf(ns) | 1006 | 1017 | 938 | 891 | 904 | 876 |

In Table 2, Tr stands for a rising time of a light emitting control signal, Tf stands for a falling time of a light emitting control signal. As shown in Table 2, the display apparatus according to the present disclosure has the shortest Tr and Tf in the gate scanning signal generating circuit GGOA and in the reset control signal generating circuit RGOA.

Table 3. Signal stability generated by several related display apparatuses and a display apparatus according to the present disclosure.

| | | Product | | | | |
|---|---|---|---|---|---|---|
| | | B | C | D | E | G |
| EMGOA | Tr (μs) | 0.73 | 0.73 | 1.58 | 1.10 | 2.23 |
| | Tf(μs) | 9.89 | 9.89 | 10.35 | 10.04 | 10.66 |

The inventors of the present disclosure also compare ΔVth margin of the second transistors in the display apparatus E and display apparatus G, the ΔVth margin of the second transistors in two display apparatuses are essentially the same.

In another aspect, the present disclosure provides a method of driving the scan circuit described herein. In some embodiments, the method includes inputting an output signal from the (n−1)-th stage of the scan circuit into the first n-th stage scan unit as an input signal thereof; outputting a first control signal from the first n-th stage scan unit to the m1 number of rows of the M rows of subpixels; subsequent to outputting the first control signal through subpixels in the m1 number of rows of the M rows of subpixels, inputting the first control signal to the second n-th stage scan unit as an input signal thereof; and outputting a second control signal from the second n-th stage scan unit to the m2 number of rows of the M rows of subpixels.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A scan circuit, comprising a plurality of stages, wherein a respective stage of the scan circuit comprises a first scan unit and a second scan unit configured to provide control signals to different rows of subpixels, output from the first scan unit being input to the second scan unit through at least one of M rows of subpixels, M being an integer ≥2.

2. The scan circuit of claim 1, wherein the first scan unit and the second scan unit are configured to provide control signals to the M rows of subpixels in a display panel, the first scan unit and the second scan unit being on two opposite sides of the M rows of subpixels, respectively.

3. The scan circuit of claim 1, wherein a length of each of the first scan unit and the second scan unit along a column direction spans over the M rows of subpixels.

4. The scan circuit of claim 1, wherein a ratio of a total number of scan units of the scan circuit to a total number of rows of subpixels is (2/M), wherein M≥4.

5. The scan circuit of claim 1, wherein M=4.

6. The scan circuit of claim 1, wherein an n-th stage of the scan circuit comprises a first n-th stage scan unit and a second n-th stage scan unit, n is an integer >1;
wherein the first n-th stage scan unit is configured to receive an output signal from a (n−1)-th stage of the scan circuit as an input signal;
an output signal from the first n-th stage scan unit is provided to m1 number of rows of the M rows of subpixels as control signals therein, and subsequently input to the second n-th stage scan unit as an input signal thereof, m1 is an integer <M; and
an output signal from the second n-th stage scan unit is provided to m2 number of rows of the M rows of subpixels as control signals therein, and subsequently input to a (n+1)-th stage of the scan circuit as an input signal thereof, m2 is an integer <M, (m1+m2)=M.

7. The scan circuit of claim 6, wherein the n-th stage of the scan circuit further comprises m1 number of output branch lines, a respective one of which configured to transmit the output signal from the first n-th stage scan unit to a respective one of the m1 number of rows of the M rows of subpixels, and m2 number of output branch lines, a respective one of which configured to transmit the output signal from the second n-th stage scan unit to a respective one of the m2 number of rows of the M rows of subpixels.

8. The scan circuit of claim 7, wherein all of the m1 number of output branch lines are electrically connected to second electrodes of a ninth transistor and a tenth transistor of the first n-th stage scan unit, and electrically connected to an input signal line of the second n-th stage scan unit; and
all of the m2 number of output branch lines are electrically connected to second electrodes of a ninth transistor and a tenth transistor of the second n-th stage scan unit, and electrically connected to an input signal line of the (n+1)-stage of the scan circuit.

9. The scan circuit of claim 6, wherein the n-th stage of the scan circuit further comprises 2M number of gate scanning signal generating units and 2M number of reset control signal generating units;
wherein a respective row of the M rows of subpixels is connected to two gate scanning signal generating units of the 2M number of gate scanning signal generating units on two opposite sides, respectively, and is connected to two reset control signal generating units of the 2M number of reset control signal generating units on two opposite sides, respectively;
wherein the first n-th stage scan unit is configured to output light emitting control signals to the m1 number of rows of the M rows of subpixels;
the second n-th stage scan unit is configured to output light emitting control signals to the m2 number of rows of the M rows of subpixels;
the 2M number of gate scanning signal generating units are configured to output gate scanning signals to the M rows of subpixels; and
the 2M number of reset control signal generating units are configured to output reset control signals to the M rows of subpixels.

10. The scan circuit of claim 1, further comprising a first voltage supply line and a second voltage supply line;
wherein transistors of a respective scan unit of the first and second scan units are arranged in a region between the first voltage supply line and the second voltage supply line.

11. The scan circuit of claim 10, wherein the respective scan unit comprises a ninth transistor and a tenth transistor, second electrodes of which are connected to an output signal line configured to output control signals from the respective scan unit to rows of subpixels;
wherein the ninth transistor and the tenth transistor are in a first region, transistors other than the ninth transistor and the tenth transistor are in a second region, the first region and the second region are sequentially arranged along extension directions of the first voltage supply line and the second voltage supply line.

12. The scan circuit of claim 11, wherein the respective scan unit further comprises a second capacitor and a third capacitor in a third region, the first region, the third region, and the second region are sequentially arranged along the extension directions of the first voltage supply line and the second voltage supply line, the first region, the third region, and the second region being non-overlapping.

13. The scan circuit of claim 1, further comprising a first signal line layer;
wherein the first signal line layer comprises a first voltage supply line, a second voltage supply line, a first connecting line, a second connecting line, a third connecting line, a fourth connecting line, and a fifth connecting line;
wherein at least portions of the first connecting line, the second connecting line, the third connecting line, the fourth connecting line, and the fifth connecting line are substantially parallel to extension directions of the first voltage supply line and the second voltage supply line.

14. The scan circuit of claim 13, wherein the first connecting line electrically connects gate electrodes of a second transistor and an eighth transistor;
the second connecting line electrically connects a second electrode of a sixth transistor with a first electrode of a seventh transistor, and is connected to a second capacitor electrode of a first capacitor through one or more vias extending through an inter-layer dielectric layer;
the third connecting line electrically connects a first electrode of the sixth transistor with a gate electrode of the seventh transistor;
the fourth connecting line electrically connects a gate electrode of a fifth transistor, a second electrode of a second transistor, a first electrode of an eleventh transistor, and a second electrode of a third transistor together; and
the fifth connecting line electrically connects a gate electrode of a fourth transistor with a second electrode of a twelfth transistor.

15. The scan circuit of claim 13, further comprising a first conductive layer;
wherein the first conductive layer comprises a sixth connecting line electrically connecting a second clock signal line with gate electrodes of a fourth transistor, a fifth transistor, and a seventh transistor; and
the sixth connecting line crosses over the fourth connecting line and the fifth connecting line, and is connected to the third connecting line through one or more vias extending through an insulating layer and an inter-layer dielectric layer.

16. The scan circuit of claim 15, wherein the first conductive layer further comprises a seventh connecting line electrically connecting a second voltage supply line with gate electrodes of an eleventh transistor and a twelfth transistor; and
the seventh connecting line crosses over the fourth connecting line.

17. The scan circuit of claim 15, wherein the first conductive layer further comprises an eighth connecting line electrically connecting a gate electrode of a second transistor with the first connecting line, a second electrode of a first transistor, and a first electrode of a twelfth transistor;
the eighth connecting line crosses over the fourth connecting line.

18. The scan circuit of claim 15, wherein the first conductive layer further comprises a ninth connecting line electrically connecting a first clock signal line with gate electrodes of a first transistor and a third transistor.

19. (canceled)

20. A display apparatus, comprising the scan circuit of claim 1, and a display panel comprising a plurality of light emitting elements.

21. A method of driving the scan circuit of claim 1, comprising:
inputting an output signal from the (n−1)-th stage of the scan circuit into the first n-th stage scan unit as an input signal thereof;
outputting a first control signal from the first n-th stage scan unit to the m1 number of rows of the M rows of subpixels;
subsequent to outputting the first control signal through subpixels in the m1 number of rows of the M rows of subpixels, inputting the first control signal to the second n-th stage scan unit as an input signal thereof; and
outputting a second control signal from the second n-th stage scan unit to the m2 number of rows of the M rows of subpixels.
